(19) United States
(12) Patent Application Publication
(10) Pub. No.: US 2024/0030134 A1
(43) Pub. Date: Jan. 25, 2024

(54) SEMICONDUCTOR DEVICE AND METHODS OF FORMATION

(71) Applicant: Taiwan Semiconductor Manufacturing Company, Ltd., Hsinchu (TW)

(72) Inventors: Chung-Liang CHENG, Changhua City (TW); Chia-Shiung TSAI, Hsin-Chu (TW); Sheng-Chau CHEN, Tainan City (TW)

(21) Appl. No.: 17/814,382

(22) Filed: Jul. 22, 2022

(51) Int. Cl. H01L 23/528; H01L 21/768; H01L 21/02; H01L 29/66; H01L 29/423; H01L 29/78; H01L 29/06

(52) U.S. Cl. CPC H01L 23/5286; H01L 21/76897; H01L 21/76877; H01L 21/02532; H01L 29/66795; H01L 29/42392; H01L 29/785; H01L 29/0665; H01L 21/76843; H01L 21/76831

(57) ABSTRACT

Some implementations described herein provide a semiconductor device and methods of formation. The semiconductor device includes a transistor structure that is electrically connected to a metal layer. Described techniques include forming an interconnect structure that electrically connects the metal layer to a backside power rail structure. The techniques include forming a first portion of the interconnect structure using a layer of silicon germanium as an etch stop and, after removal of the layer of the silicon germanium, forming a second portion of the interconnect structure.

### BACKGROUND

A semiconductor device including a transistor, such as a fin field-effect (finFET), transistor, may include a backside power rail structure. The backside power rail structure may reduce a delay in signaling speed in the semiconductor device and allow the semiconductor device to reduce a metal pitch.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor device described herein.

FIGS. 3A-3D, 4A-4S, 5A-5I, and 6A-6C are diagrams of an example implementation of forming portions of a semiconductor device including an interconnect structure and a backside power rail structure described herein.

FIG. 7 is a diagram of example components of one or more devices associated with forming an example semiconductor device including an interconnect structure and a backside power rail structure described herein.

FIG. 8 is a flowchart of an example process associated with forming an example semiconductor device including an interconnect structure and a backside power rail structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, methods of forming an interconnect structure that electrically connects a backside power rail structure to a transistor structure of a semiconductor device may include using a silicon on insulator (SOI) structure as an etch stop. In other cases, methods of forming the interconnect structure may not use an etch stop. These methods may introduce one or more inefficiencies to fabrication of the semiconductor device, including an increase in manufacturing tools and/or computing resources needed for fabrication, an increase in material costs, and/or an increase in manufacturing yield losses due to misalignment between the interconnect structure and the backside power rail structure. Additionally, misalignment between the interconnect structure and the backside power rail structure may reduce a performance (e.g., increase a delay in signaling speed) of the semiconductor device.

Some implementations described herein provide a semiconductor device and methods of formation. The semiconductor device includes a transistor structure that is electrically connected to a metal layer. Described techniques include forming an interconnect structure that electrically connects the metal layer to a backside power rail structure. The techniques include forming a first portion of the interconnect structure using a layer of silicon germanium as an etch stop and, after removal of the layer of the silicon germanium, forming a second portion of the interconnect structure.

In this way, manufacturing efficiencies relative to manufacturing efficiencies associated with not using the layer of silicon germanium may be increased. Additionally, a likelihood of the interconnect structure making electrical contact with the backside rail structure may increase due to improve a performance of the semiconductor device relative to a semiconductor device fabricated not using the layer of silicon germanium.

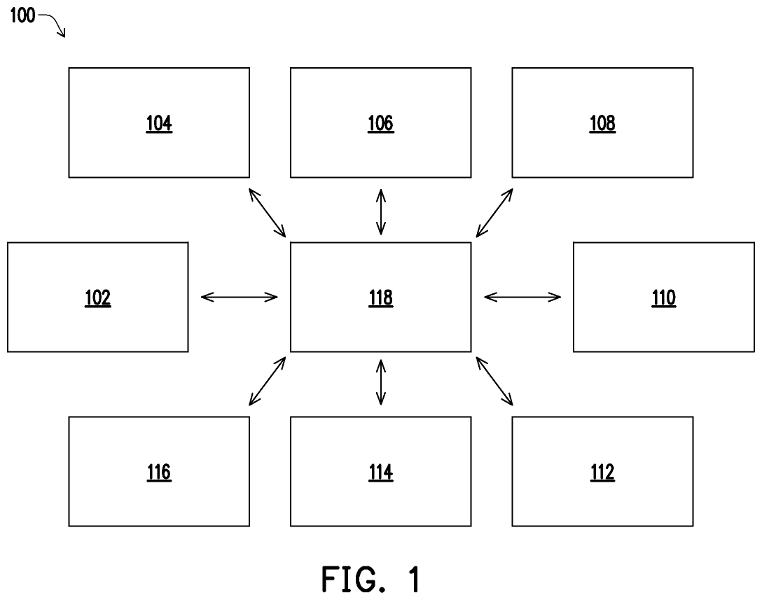

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, a bonding tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The bonding tool 116 is a semiconductor processing tool that is capable of bonding two or more wafers (or two or more semiconductor substrates, or two or more semiconductor devices) together. For example, a bonding tool may include a eutectic bonding tool that is capable of forming a eutectic bond between two or more wafers together. In these examples, the bonding tool may heat the two or more wafers to form a eutectic system between the materials of the two or more wafers.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

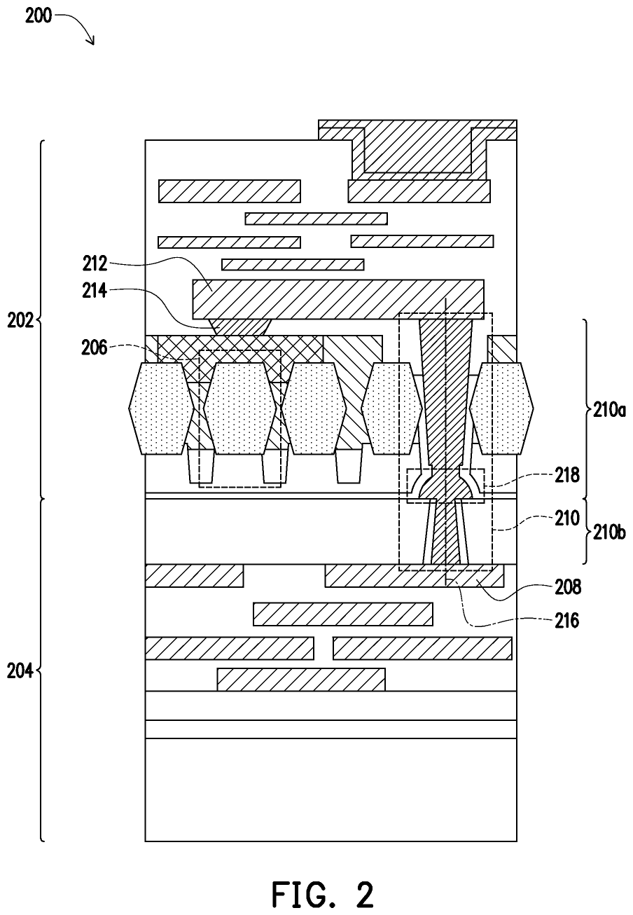

In some implementations, and as described in greater detail in connection with FIGS. 2-8 and elsewhere herein, one or more of the semiconductor processing tools 102-116 may perform a combination of semiconductor processing operations. For example, the combination of semiconductor processing operations may include forming a layer of silicon germanium material on a silicon substrate. The combination of semiconductor processing operations may include forming a first plurality of layers of materials including a bottom layer of semiconductor material on the layer of silicon germanium material, where the first plurality of layers of materials are arranged in a first direction that is perpendicular to the silicon substrate. The combination of semiconductor processing operations may include forming a recess through the first plurality of layers and to a surface of the layer of silicon germanium material. The combination of semiconductor processing operations may include forming, within the recess, a first portion of an interconnect structure. The combination of semiconductor processing operations may include forming a metal layer structure that makes electrical contact with the first portion of the interconnect structure. The combination of semiconductor processing operations may include removing the silicon substrate. The combination of semiconductor processing operations may include removing the layer of silicon germanium material to expose a bottom surface of the bottom layer of semiconductor material. The combination of semiconductor processing operations may include forming a second plurality of layers of materials on the bottom surface of the bottom layer of semiconductor material, where the second plurality of layers of materials are arranged in a second direction that is perpendicular to the bottom layer of semiconductor material and opposite the first direction. The combination of semiconductor processing operations may include forming a second portion of the interconnect structure through the second plurality of layers of materials. The combination of semiconductor processing operations may include forming a backside power rail structure that makes electrical contact with the second portion of the interconnect structure

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

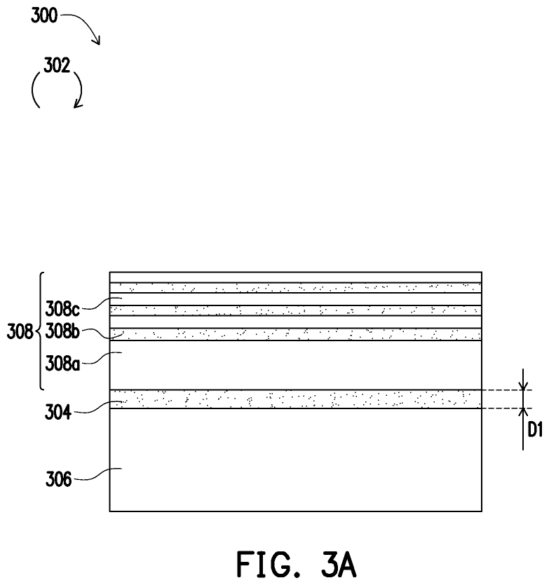

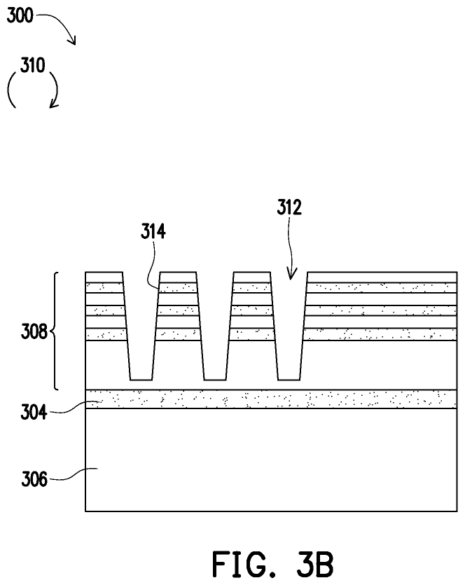

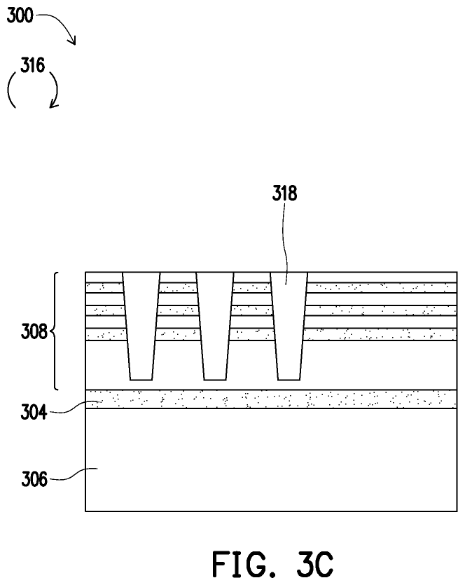

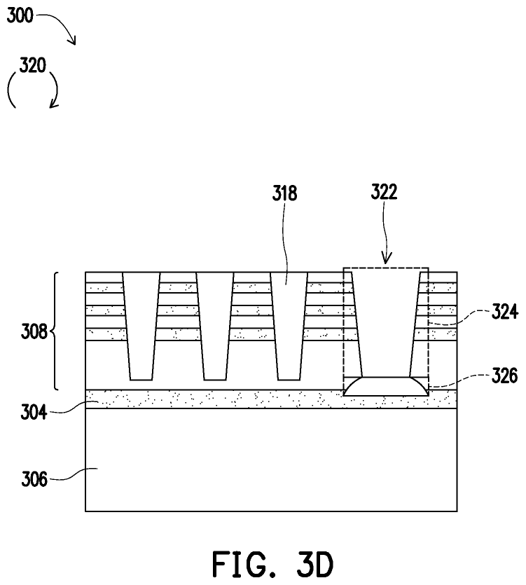

FIG. 2 is a diagram of an example semiconductor device 200 described herein. As described in greater detail in connection with FIGS. 3A-8, one or more of the semiconductor processing tools 102-116 may perform a series or series of one or more operations that include depositing and using different layers of materials (e.g., semiconductor materials, conductive metal materials, and/or dielectric materials) to form the features of the semiconductor device 200 of FIG. 2. In some implementations, the operations include using a layer of silicon germanium material (e.g., a temporary or sacrificial layer).

As shown in the side view of FIG. 2 (a section view), the semiconductor device 200 includes a portion 202 (e.g., a first portion or a top portion of the semiconductor device 200) connected to a portion 204 (e.g., a second portion or a bottom portion of the semiconductor device 200). The portion 202 includes a transistor structure 206 (e.g., a fin field-effect transistor structure or a gate-all-around transistor structure, among other examples). The portion 204 includes a backside power rail structure 208.

The backside power rail structure 208 may be configured to provide a base voltage (VB) to the transistor structure 206 through an interconnect structure 210, a metal layer structure 212, and an interconnect structure 214.

The interconnect structure 210 may include a portion 210a and a portion 210b. The portion 210a (e.g., a first portion or a top portion of the interconnect structure 210) may be located along a central, vertical axis 216 and include an approximately hemispherical structure 218 (e.g., at an interface between the portions 202 and 204 of the semiconductor device 200. The portion 210b (e.g., a second portion or a bottom portion of the interconnect structure 210) may be approximately co-located along the central, vertical axis 216 within the portion 204 of the semiconductor device 200 and include an end that joins with the approximately hemispherical structure 218 of the portion 210a.

In some implementations, a diameter of a bottom surface of the approximately hemispherical structure 218 may accommodate a stack up of manufacturing tolerances during formation of the interconnect structure 210 (e.g., during alignment and/or joining of the portion 210b to the portion 210a, among other examples). In other words, the diameter of the bottom surface of the approximately hemispherical structure 218 may contribute to improving a likelihood of electrical continuity and/or electrical contact between the transistor structure 206 and the backside power rail structure 208 to increase a yield of semiconductor device 200.

As described in greater detail in connection with FIGS. 3A-8 and elsewhere herein, a device (e.g., the semiconductor device 200) has a top portion (e.g., the portion 202) including a metal layer structure (e.g., the metal layer structure 212). The device includes a bottom portion (e.g., the portion 204) below the top portion including a backside power rail structure (e.g., the backside power rail structure 208). The device includes an interconnect structure (e.g., the interconnect structure 210) electrically connecting the metal layer structure to the backside power rail structure. The interconnect structure includes a first portion (e.g., the portion 210a) located along a central, vertical axis (e.g., the central, vertical axis 216) within the top portion. The first portion has an approximately hemispherical structure (e.g., the approximately hemispherical structure 218) at an interface between the top portion and the bottom portion. The interconnect structure includes a second portion (e.g., the portion 210b) approximately co-located along the central, vertical axis within the bottom portion. The second portion has an end that joins with the approximately hemispherical structure of the first portion.

Additionally, or alternatively, the device includes a transistor structure (e.g., the transistor structure 206) having a plurality of channel structures. The device includes a metal layer structure (e.g., the metal layer structure 212) above the plurality of channel structures. The device includes a first interconnect structure (e.g., the interconnect structure 214) above the transistor structure that electrically connects the transistor structure to the metal layer structure. The device includes a second interconnect structure (e.g., the interconnect structure 210) adjacent to the transistor structure. The second interconnect structure includes a first end electrically connected to the metal layer structure, a second end electrically connected to a backside power rail structure (e.g., the backside power rail structure 208), and a bowed-profile portion (e.g., the approximately hemispherical structure 218) between the first end and the second end.

As indicated above, FIG. 2 is provided as an example. Other examples may differ from what is described with regard to FIG. 2. For example, another semiconductor device including the backside power rail structure 208, the interconnect structure 210, and the metal layer structure 212 may include additional features, fewer features, different features, or differently arranged features than those shown in FIG. 2.

FIGS. 3A-3D are diagrams of an example implementation 300 of forming portions of a semiconductor device including an interconnect structure and a backside power rail structure described herein. The portions of FIGS. 3A-3D may correspond to portions of the semiconductor device 200 of FIG. 2. The portions of implementation 300 include layers of material that may be used as part of the transistor structure 206 and a layer of silicon germanium material (e.g., a temporary or sacrificial layer). The portions of implementation 300 further include a recess for the portion 210a of the interconnect structure 210.

As shown in FIG. 3A, one or more of the semiconductor processing tools 102-116 may perform a series of one or more operations 302 to form one or more layers of the semiconductor device 200. The series of one or more operations 302 may include, for example, the deposition tool 102 depositing a layer of silicon germanium material 304 over a silicon substrate in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of silicon germanium material 304 after the deposition tool 102 deposits the layer of silicon germanium material 304.

In some implementations, a thickness D1 of the layer of silicon germanium material 304 may be included in a range of approximately 10 nanometers to approximately 100 nanometers. If the thickness D1 is less than approximately 10 nanometers, the layer of silicon germanium material 304 may be ineffective for subsequent use as an etch stop. If the thickness D1 is greater than approximately 100 nanometers, the semiconductor device 200 may be subject to high lateral stresses during subsequent manufacturing steps. However, other values and ranges for the thickness D1 are within the scope of the present disclosure.

The series of one or more operations 302 may further include the deposition tool 102 depositing a plurality of layers of materials 308 over the layer of silicon germanium material 304 in a PVD operation, an ALD operation, a CVD operation, an epitaxy operation, an oxidation operation, another type of deposition operation described in connection with FIG. 1, and/or another suitable deposition operation. The plurality of layers of materials 308 may include, for example, a bottom layer of a semiconductor material 308a (e.g., a silicon material, among other examples), a layer (or multiple layers) of a sacrificial material 308b (e.g., a silicon germanium material, among other example) for a subsequent replacement gate operation, and a layer (or multiple layers) of a semiconductor material 308c (e.g., a silicon material, among other examples) corresponding to channel layers of the transistor structure 206. In some implementations, the planarization tool 110 planarizes the plurality of layers of materials 308 after the deposition tool 102 deposits the plurality of layers of materials 308. As shown in FIG. 3A, the layer of silicon germanium material 304 and the plurality of layers of materials 308 are arranged in a direction that is perpendicular to the silicon substrate 306.

As shown in FIG. 3B, a combination of one or more of the semiconductor processing tools 102-116 may perform a series of one or more operations 310 to form recesses 312 extending into the plurality of layers of materials 308. In some implementations, a pattern in a photoresist layer is used to etch a recess to form the recesses 312. In these implementations, the deposition tool 102 forms a photoresist layer over the plurality of layers of materials 308. The exposure tool 104 exposes the photoresist layer to a radiation source to pattern the photoresist layer. The developer tool 106 develops and removes portions of the photoresist layer to expose the pattern. The etch tool 108 etches the recesses 312 based on the pattern to form the recesses 312 extending into the plurality of layers of materials 308. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the recesses 312 based on a pattern. Furthermore, and as part of forming the recesses 312, portions of the layers of semiconductor material 308c may be removed to form one or more channel structures 314.

As shown in FIG. 3C, a combination of one or more of the semiconductor processing tools 102-116 may perform a series of one or more operations 316 to form dielectric structures 318 in the recesses 312. In some implementations, portions of the dielectric structures 318 may correspond to portions of shallow trench isolation (STI) regions of a transistor structure (e.g., the transistor structure 206). As shown in FIG. 3C, the dielectric structures 318 are formed in the recesses 312. The deposition tool 102 may deposit a layer of a dielectric material included in the dielectric structures 318 (e.g., a silicon oxide (SiO₂) material or other dielectric material, among other examples) in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of dielectric material after the deposition tool 102 deposits the dielectric material as part of forming the dielectric structures 318.

As shown in FIG. 3D, a combination of one or more of the semiconductor processing tools 102-116 may perform a series of one or more operations 320 to form a recess 322 extending through the plurality of layers of materials 308 to expose a surface of the layer of silicon germanium material 304. In these implementations, the deposition tool 102 forms a photoresist layer over the plurality of layers of materials 308. The exposure tool 104 exposes the photoresist layer to a radiation source to pattern the photoresist layer. The developer tool 106 develops and removes portions of the photoresist layer to expose the pattern.

As part of the series of one or more operations 320, the etch tool 108 etches the recess 322 based on the pattern to form the recess extending into the plurality of layers of materials 308. In some implementations, the etch operation may correspond to a multi-step etching process. For example, the etch tool 108 may form an elongated region 324 of the recess 322 using a dry etch technique, among other examples. In some implementations, the elongated region 324 may include a tapered portion and/or correspond to a tapered shape. Additionally, or alternatively, the etch tool 108 may form an approximately hemispherical region (e.g., a bowed-profile region) using a wet etch technique. Such a technique may include a wet chemical etch operation to laterally etch the approximately hemispherical region 326 using a tetramethyl ammonium hydroxide (TAH) solution or an ammonia (NH3) solution, among other examples. In some implementations, the etch tool 108 forms the approximately hemispherical region 326 below the elongated region 324 and on (or above) the surface of the layer of silicon germanium material 304. In some implementations, and as part of the series of one or more operations 320, a photoresist removal tool removes the remaining portions of the photoresist layer (e.g., using a chemical stripper, plasma ashing, and/or another technique). In some implementations, a hard mask layer is used as an alternative technique for etching the recess 322 based on a pattern.

As indicated above, FIGS. 3A-3D are provided as examples. Other examples may differ from what is described with regard to FIGS. 3A-3D.

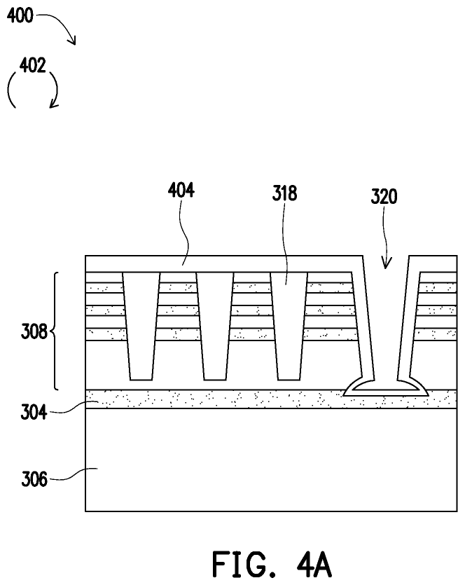

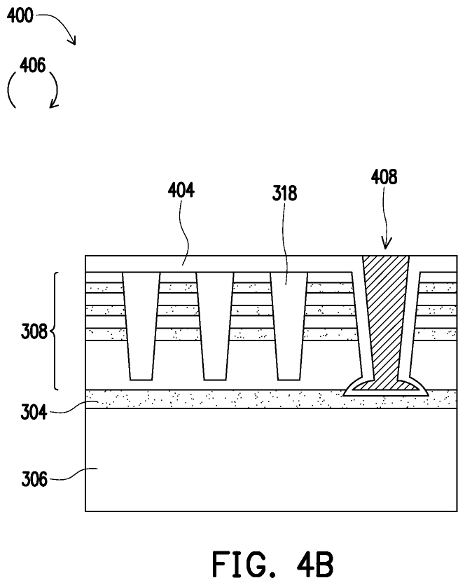

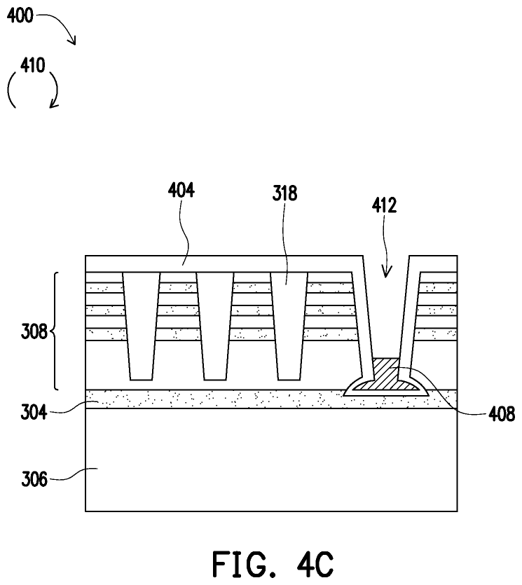

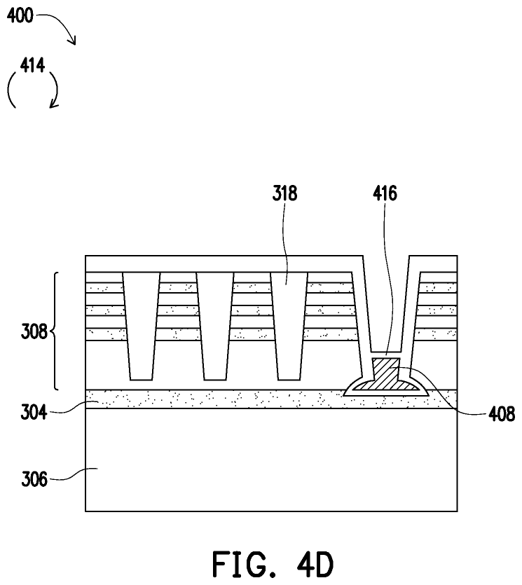

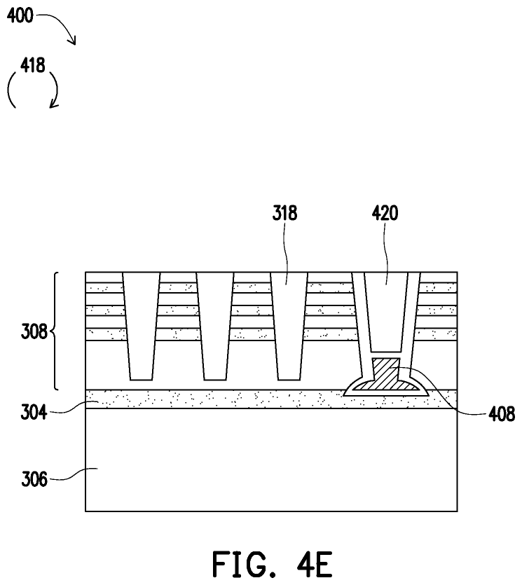

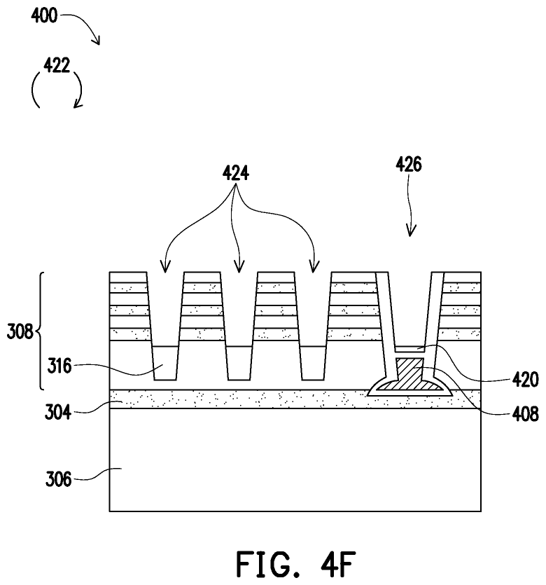

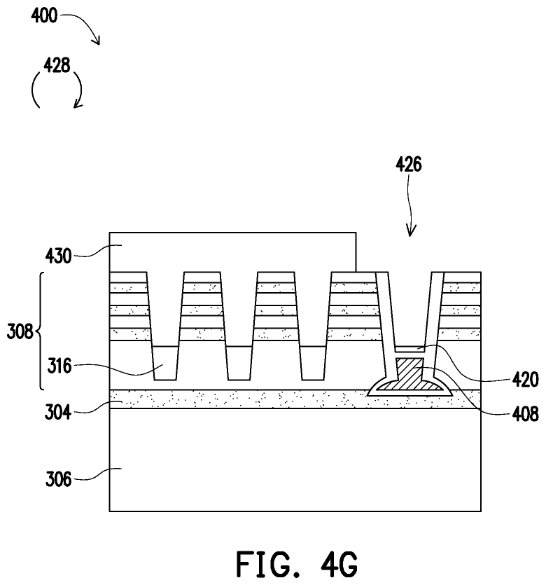

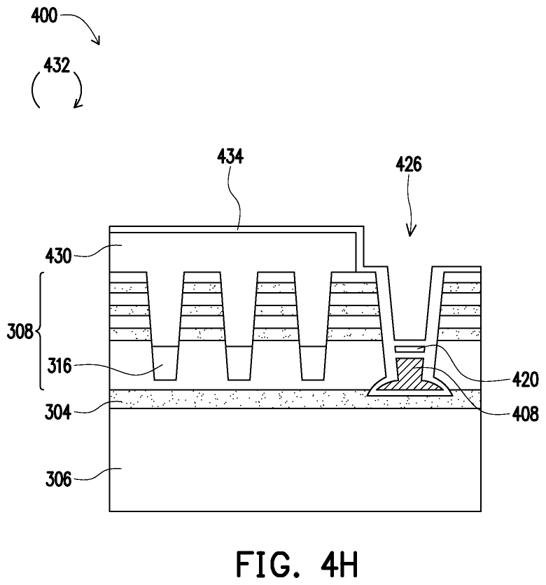

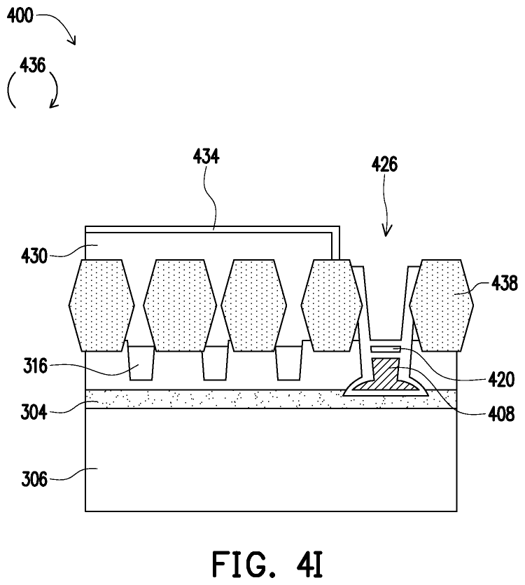

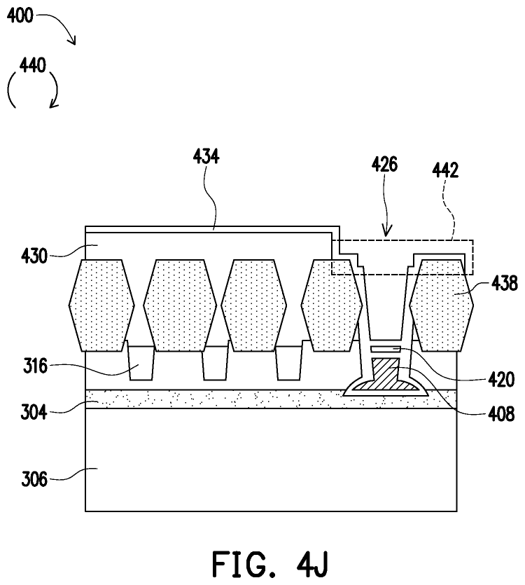

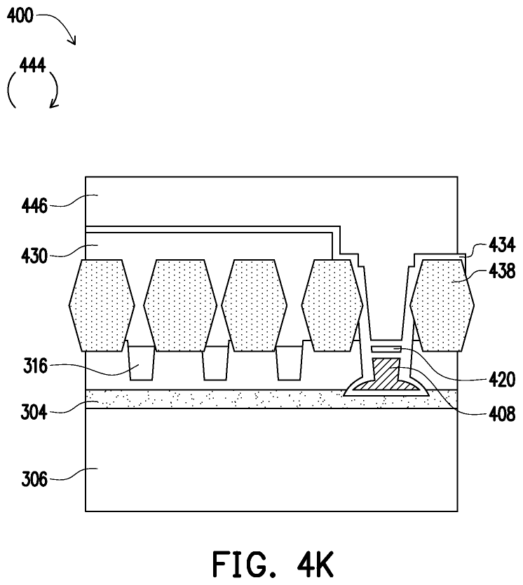

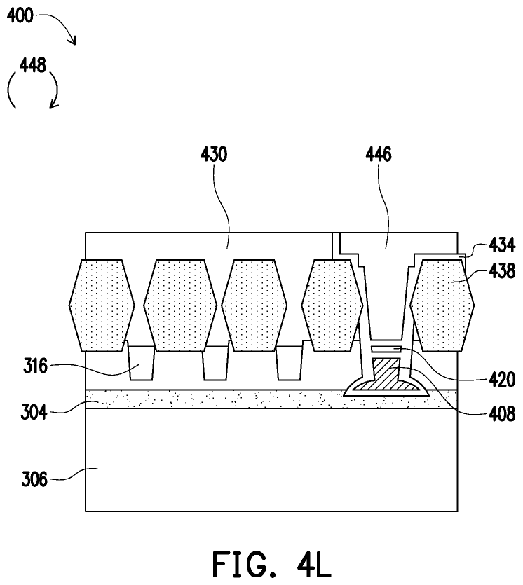

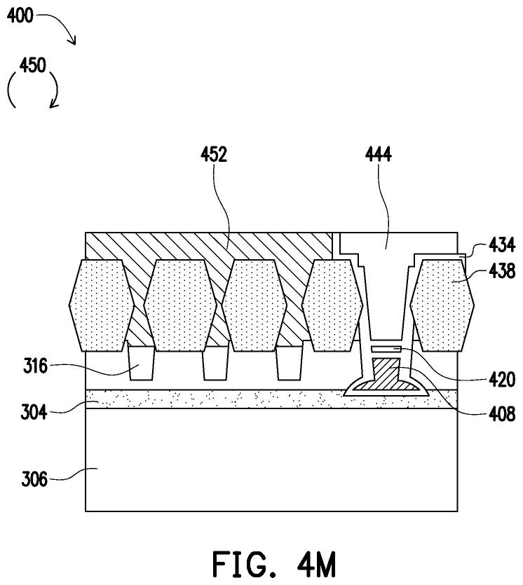

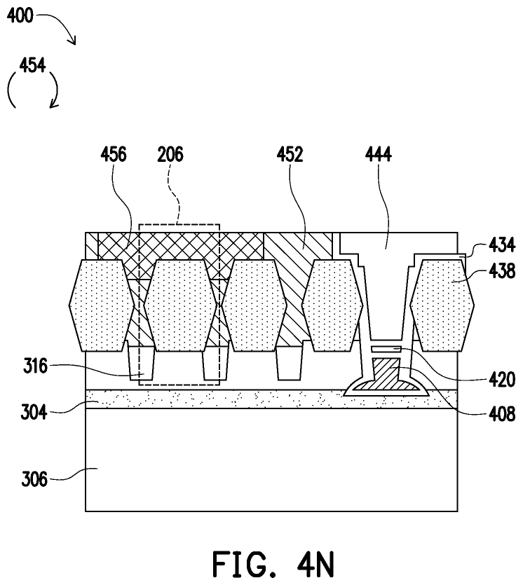

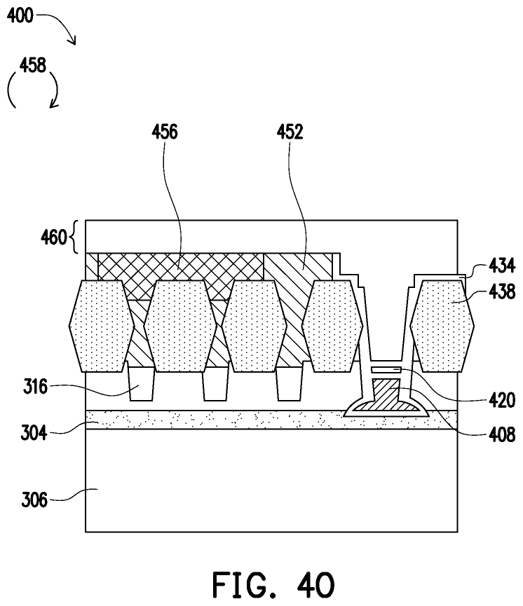

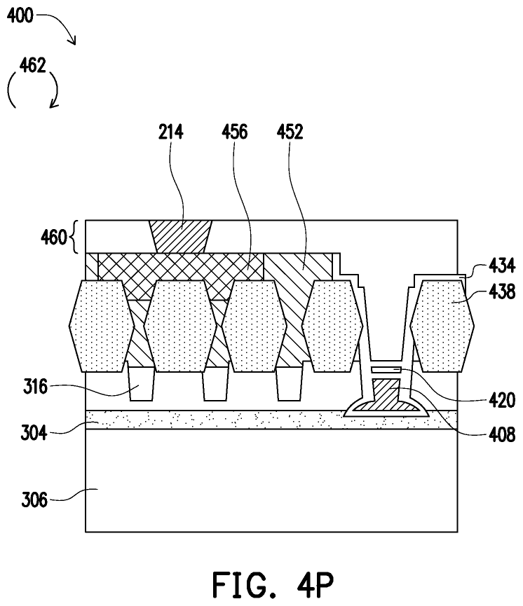

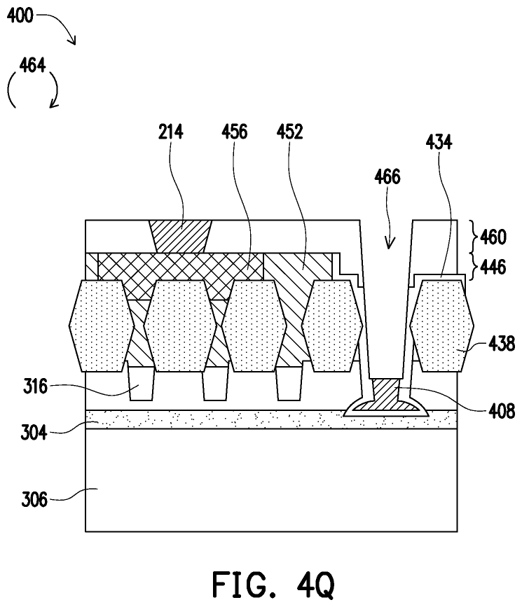

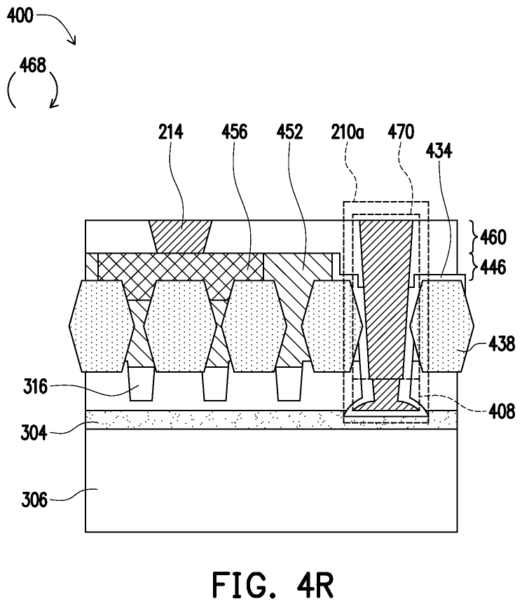

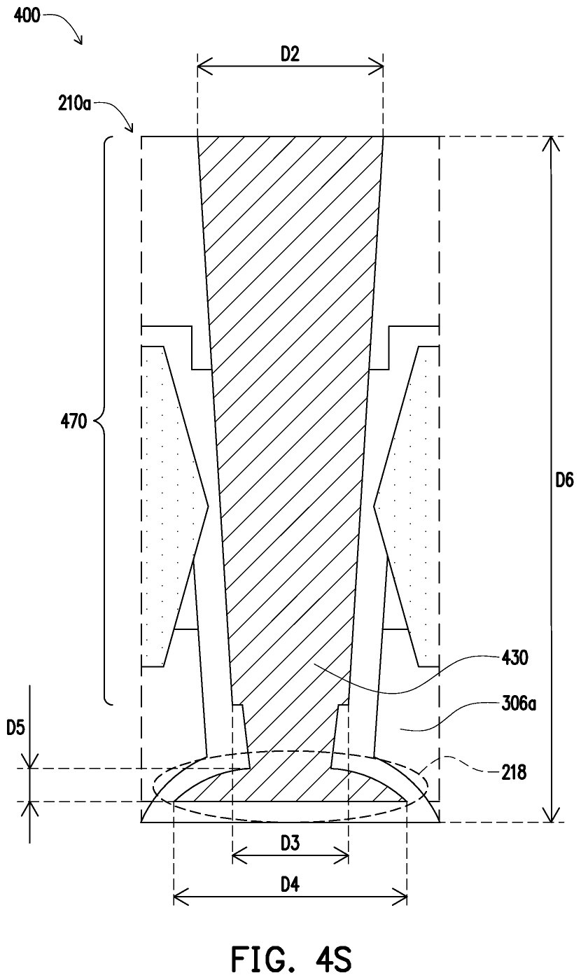

FIGS. 4A-4S are diagrams of an example implementation 400 of forming portions of a semiconductor device including an interconnect structure and a backside power rail structure described herein. In FIGS. 4A-4S, various operations are used to form portions of the semiconductor device 200 of FIG. 2. The portions of the semiconductor device 200 in implementation 400 include the portion 210a of the interconnect structure 210.

As shown in FIG. 4A, one or more of the semiconductor processing tools 102-116 may perform a series of one or more operations 402 to form a layer of dielectric liner material 404 (e.g., a silicon nitride (SiN) material or other dielectric material, among other examples) over the plurality of layers of materials 308 and on surfaces of the recess 322. The deposition tool 102 may deposit a layer of dielectric liner material 404 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of dielectric liner material 404 after the deposition tool 102 deposits the layer of dielectric liner material 404.

As shown in FIG. 4B, one or more of the semiconductor processing tools 102-116 may perform a series of one or more operations 406 to form a plug structure 408 within the recess 322. The deposition tool 102 may deposit a layer of a conductive material (e.g., a titanium nitride (TiN) material or a tungsten (W) material, among other examples) in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of conductive material after the deposition tool 102 deposits the layer of conductive material as part of forming the plug structure 408.

As shown in FIG. 4C, a combination of one or more of the semiconductor processing tools 102-116 may perform a series of one or more operations 410 to remove a portion of the plug structure 408 and form a recess 412. In these implementations, the deposition tool 102 forms a photoresist layer on the layer of dielectric liner material 404. The exposure tool 104 exposes the photoresist layer to a radiation source to pattern the photoresist layer. The developer tool 106 develops and removes portions of the photoresist layer to expose the pattern.

As part of the series of one or more operations 410, the etch tool 108 etches the recess 412 based on the pattern. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the recess 412 based on a pattern.

As shown in FIG. 4D, a combination of one or more of the semiconductor processing tools 102-116 may perform a series of one or more operations 414 that includes forming a layer of dielectric liner material 416 (e.g., a silicon nitride (SiN) material or other dielectric material, among other examples) on a remaining portion of the plug structure 408 and over the plurality of layers of materials 308. The deposition tool 102 may deposit the layer of dielectric liner material 416 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of dielectric liner material 416 after the deposition tool 102 deposits the layer of dielectric liner material 416.

As shown in FIG. 4E, a combination of one or more of the semiconductor processing tools 102-116 may perform a series of one or more operations 418 to form an oxide fill structure 420 on the layer of dielectric liner material 416 and within the recess 412. As part of the series of one or more operations 418, the deposition tool 102 may deposit a layer of an oxide material (e.g., a silicon dioxide (SiO₂) material or another dielectric material, among other examples) in a PVD operation, an ALD operation, a CVD operation, an epitaxy operation, an oxidation operation, another type of deposition operation described in connection with FIG. 1, and/or another suitable deposition operation. In some implementations, and as part of forming the oxide fill structure 420, the planarization tool 110 planarizes the layer of dielectric liner material 404, the layer of dielectric liner material 416, and the layer of oxide material after the deposition tool 102 deposits the layer of oxide material.

As shown in FIG. 4F, a combination of one or more of the semiconductor processing tools 102-116 may perform a series of one or more operations 422 to remove portions of the dielectric structures 318 to form recesses 424 and remove a portion of the oxide fill structure 420 to form a recess 426. In some implementations, a pattern in a photoresist layer is used to etch the dielectric structures 318 to form the recesses 424 and to etch the oxide fill structure 420 to form the recess 426. In these implementations, the deposition tool 102 forms the photoresist layer over the plurality of layers of materials 308, the dielectric structures 318, and the oxide fill structure 420. The exposure tool 104 exposes the photoresist layer to a radiation source to pattern the photoresist layer. The developer tool 106 develops and removes portions of the photoresist layer to expose the pattern. The etch tool 108 etches the dielectric structures 318 and the oxide fill structure 420 based on the pattern to form the recesses 424 and the recess 426. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the dielectric structures 318 and the oxide fill structure 420 based on a pattern.

As shown in FIG. 4G, one or more of the semiconductor processing tools 102-116 may perform a series of one or more operations 428 to form a dummy gate structure 430 over the plurality of layers of materials 308 and in the recesses 426. As part of the series of one or more operations 428, the deposition tool 102 may deposit a layer of a dielectric material (e.g., an silicon dioxide (SiO₂) material or another dielectric material, among other examples) over the plurality of layers of materials 308, in the recesses 424, and in the recess 426 in a PVD operation, an ALD operation, a CVD operation, an epitaxy operation, an oxidation operation, another type of deposition operation described in connection with FIG. 1, and/or another suitable deposition operation. In some implementations, and as part of forming the dummy gate structure 430, the planarization tool 110 planarizes the layer of dielectric material after the deposition tool 102 deposits the layer of dielectric material.

In some implementations, a pattern in a photoresist layer is used to etch the layer of dielectric material to form the dummy gate structure 430. In these implementations, the deposition tool 102 forms the photoresist layer over the layer of dielectric material. The exposure tool 104 exposes the photoresist layer to a radiation source to pattern the photoresist layer. The developer tool 106 develops and removes portions of the photoresist layer to expose the pattern. The etch tool 108 etches the layer of dielectric material based on the pattern to form the dummy gate structure 430 and to “reopen” the recess 426. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the dummy gate structure 430 based on a pattern.

As shown in FIG. 4H, one or more of the semiconductor processing tools 102-116 may perform a series of one or more operations 432 to form a layer of spacer material 434 (e.g., a silicon oxide (SiO₂) material or other dielectric material, among other examples) on the dummy gate structure 430 and on surfaces within the recess 426. For example, the deposition tool 102 may deposit the layer of spacer material 434 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of spacer material 434 after the deposition tool 102 deposits the layer of spacer material 434.

As shown in FIG. 41, a combination of one or more of the semiconductor processing tools 102-116 may perform a series of one or more operations 436 to form epitaxial structures 438. The epitaxial structures 438 may correspond to source/drain regions of a transistor structure (e.g., the transistor structure 206). As part of the series of one or more operations 436, a pattern in a photoresist layer is used to etch source/drain recesses to form the epitaxial structures 438. In these implementations, the deposition tool 102 forms the photoresist layer over the plurality of layers of materials 308. The exposure tool 104 exposes the photoresist layer to a radiation source to pattern the photoresist layer. The developer tool 106 develops and removes portions of the photoresist layer to expose the pattern. The etch tool 108 etches the plurality of layers of materials 308 based on the pattern to form the source/drain recesses in the plurality of layers of materials 308. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the plurality of layers of materials 308 based on a pattern.

Additionally, or alternatively and as part of the series of one or more operations 436, the deposition tool 102 may deposit a layer of an epitaxial material (e.g., a silicon germanium material, among other examples) on surfaces of the source/drain recesses in a PVD operation, an ALD operation, a CVD operation, an epitaxy operation, an oxidation operation, another type of deposition operation described in connection with FIG. 1, and/or another suitable deposition operation.

As shown in FIG. 4J, a combination of one or more of the semiconductor processing tools 102-116 may perform a series of one or more operations 440 to form a contact etch stop structure 442 on or above an upper portion of the recess 426. For example, the deposition tool 102 may deposit a layer of contact etch stop material (e.g., a silicon nitride (SiₓN_{y}) material or a nitrogen (N), silicon (Si), and/or carbon (C) containing material, among other examples) on the layer of spacer material 434 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of contact etch stop material after the deposition tool 102 deposits the layer of contact etch stop material.

In some implementations, a pattern in a photoresist layer is used to etch the contact etch stop material to form the contact etch stop structure 442. In these implementations, the deposition tool 102 forms the photoresist layer on the layer of contact etch stop material. The exposure tool 104 exposes the photoresist layer to a radiation source to pattern the photoresist layer. The developer tool 106 develops and removes portions of the photoresist layer to expose the pattern. The etch tool 108 etches the layer of contact etch stop material based on the pattern to form the contact etch stop structure 442 from the contact etch stop layer. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the layer of contact etch stop material based on a pattern.

As shown in FIG. 4K, one or more of the semiconductor processing tools 102-116 may perform a series of one or more operations 444 to form a layer of interlayer dielectric (ILD) material 446 (e.g., a silicon oxide (SiO₂) material or other dielectric material, among other examples). For example, the deposition tool 102 may deposit the layer of ILD material 446 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of ILD material 446 after the deposition tool 102 deposits the layer of ILD material 446.

As shown in FIG. 4L, one or more of the semiconductor processing tools 102-116 may perform a series of one or more operations 448 to remove portions of the layer of spacer material 434 and a portion of the ILD material 446. In some implementations, the planarization tool 110 planarizes the layer of spacer material 434 and the layer of the ILD material 446.

As shown in FIG. 4M, one or more of the semiconductor processing tools 102-116 may perform a series of one or more operations 450 to form a gate structure 452. The gate structure 452 may correspond to a metal gate structure of a transistor structure (e.g., the transistor structure 206). The series of one or more operations 450 may include, for example, a replacement gate operation in which a pattern in a photoresist layer is used to etch (e.g., remove) the dummy gate structure 430. In these implementations, the deposition tool 102 forms the photoresist layer on the dummy gate structure 430 and on remaining portions of the layer of spacer material 434 and layer of ILD material 446. The exposure tool 104 exposes the photoresist layer to a radiation source to pattern the photoresist layer. The developer tool 106 develops and removes portions of the photoresist layer to expose the pattern. The etch tool 108 etches the dummy gate structure 430 based on the pattern to remove the dummy gate structure 430. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the dummy gate structure 430 based on a pattern.

As part of the series of one or more operations 450, the deposition tool 102 may deposit a layer of gate material (e.g., a metal material and/or a layer of a high dielectric constant (high-k) material, among other examples) in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of gate material after the deposition tool 102 deposits the layer of gate material.

In some implementations and as part of the series of one or more operations 450, a pattern in a photoresist layer is used to etch the layer of gate material to form the gate structure 452. In these implementations, the deposition tool 102 forms the photoresist layer on the layer of gate material. The exposure tool 104 exposes the photoresist layer to a radiation source to pattern the photoresist layer. The developer tool 106 develops and removes portions of the photoresist layer to expose the pattern. The etch tool 108 etches the layer of the gate material based on the pattern to form the gate structure 452 from the layer of gate material. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the layer of gate material based on a pattern.

As shown in FIG. 4N, a combination of more of the semiconductor processing tools 102-116 may perform a series of one or more operations 454 to form a contact structure 456. The contact structure 456 may correspond to a contact structure (e.g., a source/drain or “MD” contact structure) for the transistor structure 206. In some implementations, a pattern in a photoresist layer is used to etch the gate structure 452 to form a recess for the contact structure 456. In these implementations, the deposition tool 102 forms the photoresist layer on the gate structure. The exposure tool 104 exposes the photoresist layer to a radiation source to pattern the photoresist layer. The developer tool 106 develops and removes portions of the photoresist layer to expose the pattern. The etch tool 108 etches the recess for the contact structure 456 based on the pattern to form the recess in the gate structure 452. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the gate structure 452 based on a pattern.

Additionally, or alternatively, the series of one or more operations 454 may include the deposition tool 102 depositing a layer of a conductive material (e.g., a ruthenium (Ru) material, a tungsten (W) material, or cobalt (Co) material, among other examples) included in the contact structure 456 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of conductive material after the deposition tool 102 deposits the layer of conductive material as part of forming the contact structure 456.

As shown in FIG. 4O, a combination of one or more of the semiconductor processing tools 102-116 may perform a series of one or more operations 458 that include forming a layer of dielectric material 460 over the gate structure 452 and the contact structure 456. The series of one or more operations 458 may include the deposition tool 102 depositing the layer of dielectric material (e.g., a silicon oxide (SiO₂) material or other dielectric material, among other examples) using a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of dielectric material 460 after the deposition tool 102 deposits the layer of dielectric material 460.

As shown in FIG. 4P, a combination of one or more of the semiconductor processing tools 102-116 may perform a series of one or more operations 462 that include forming the interconnect structure 214 in the layer of dielectric material 460. In some implementations, a pattern in a photoresist layer is used to etch a recess for the interconnect structure 214. In these implementations, the deposition tool 102 forms the photoresist layer on the layer of dielectric material 460. The exposure tool 104 exposes the photoresist layer to a radiation source to pattern the photoresist layer. The developer tool 106 develops and removes portions of the photoresist layer to expose the pattern. The etch tool 108 etches the recess for the interconnect structure 214 based on the pattern to form the recess in the layer of dielectric material. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique).

In some implementations, a hard mask layer is used as an alternative technique for etching the recess based on a pattern.

Additionally, or alternatively, the series of one or more operations 462 may include the deposition tool 102 depositing a layer of a conductive material (e.g., a titanium nitride (TiN) material or a tungsten (W) material, among other examples) included in the interconnect structure 214 using a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of conductive material after the deposition tool 102 deposits the layer of conductive material as part of forming the interconnect structure 214.

As shown in FIG. 4Q, a combination of one or more of the semiconductor processing tools 102-116 may perform a series of one or more operations 464 that include forming a recess 466 through the layer of dielectric material 460 (and/or the layer of ILD material 446 and/or the layer of spacer material 434) to expose the remaining portion of the plug structure 408. In some implementations, a pattern in a photoresist layer is used to etch the layer of dielectric material 460 (and/or the layer of ILD material 446 and/or the layer of spacer material 434) to form the recess 466. In these implementations, the deposition tool 102 forms the photoresist layer on the layer of dielectric material 460. The exposure tool 104 exposes the photoresist layer to a radiation source to pattern the photoresist layer. The developer tool 106 develops and removes portions of the photoresist layer to expose the pattern. The etch tool 108 etches the layer of dielectric material 460 (and/or the layer of ILD material 446 and/or the layer of spacer material 434) based on the pattern to form the recess 466 and expose the remaining portion of the plug structure 408. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the layer of dielectric material (and/or the layer of ILD material 446) based on a pattern.

As shown in FIG. 4R, one or more of the semiconductor processing tools 102-116 may perform a series of one or more operations 468 to form the portion 210a of the interconnect structure 210. As part of the series of one or more operations 468, the deposition tool 102 may deposit a layer of a conductive material (e.g., a titanium nitride (TiN) material or a tungsten (W) material, among other examples) included in the portion 210a in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of conductive material after the deposition tool 102 deposits the layer of conductive material as part of forming the portion 210a. As shown in FIG. 4R, the remaining portion of the plug structure 408 joins to an elongated structure 470 (e.g., a remaining portion of the layer of conductive material) to form the portion 210a of the interconnect structure 210.

As shown in FIG. 4S, the portion 210a formed by operations described in connection with FIGS. 4A-4R may include one or more geometric and/or dimensional properties. For example, a width D2 (e.g., a top width) of the elongated structure 470 may be included in a range of approximately of approximately 15 nanometers to approximately 100 nanometers. If D2 is less than approximately 15 nanometers, a corresponding recess (e.g., the recess 466) may be too small for a fill process (e.g., a deposition operation) and cause defects in the elongated structure 470. If the width D2 is greater than approximately 100 nanometers, a dimension/pitch of a device including the portion 210a (e.g., the semiconductor device 200) might be increased to increase a cost of manufacturing. However, other values and ranges for the width D2 are within the scope of the present disclosure.

Additionally, or alternatively, a width D3 (e.g., a bottom width) of the elongated structure 470 may be included in a range of approximately 10 nanometers to approximately nanometers. If the width D3 is less than approximately 10 nanometers, a corresponding recess (e.g., the recess 466) may be too small for a fill process (e.g., a deposition operation) and cause defects in the elongated structure 470. If the width D3 is greater than approximately 50 nanometers, the corresponding recess may have been over etched and defects may be present in the layer of semiconductor material 308a. However, other values and ranges for the width D3 are within the scope of the present disclosure.

In connection with the widths D2 and D3, the elongated structure 470 may include a shape. For example, the elongated structure may include a tapered shape or a conical shape, among other examples.

The approximately hemispherical structure 218 may include a width D4. For example, the width D4 may be included in a range of approximately 20 nanometers to approximately 60 nanometers. If width D4 is less than approximately 20 nanometers, the approximately hemispherical structure 218 may be undersized and cause difficulties in a subsequent operation to align and join the portion 210a with another portion (e.g., the portion 210b). If the width D4 is greater than approximately 60 nanometers, an approximately hemispherical region (e.g., the approximately hemispherical region 326) in which the approximately hemispherical structure 218 is formed may have been over-etched and defects may be present in the layer of semiconductor material 308a. However, other values and ranges for the width D4 are within the scope of the present disclosure.

The approximately hemispherical structure 218 may include a height D5. For example, the height D5 may be included in a range of approximately 5 nanometers to approximately 20 nanometers. If the height D5 is less than approximately 5 nanometers, the approximately hemispherical structure 218 may be undersized and cause defects during a subsequent etching of a recess to join another portion (e.g., the portion 210b) with the portion 210a. If the height D5 greater than approximately 20 nanometers, an approximately hemispherical region (e.g., the approximately hemispherical region 326) in which the approximately hemispherical structure 218 is formed may have been over-etched and defects may be present in the layer of semiconductor material 308a.

In some implementations, the portion 210a includes a length D6. For example, the length D6 may be included in a range of approximately 100 nanometers to approximately 1000 nanometers. If the length D6 less than approximately 100 nanometers, the portion 210a may be incompatible with a multi-layer finFET or GAA transistor (e.g., the transistor structure 206). If the length D6 is greater than approximately 1000 nanometers, a cost of manufacturing a device including the portion 210a (e.g., the semiconductor device 200) may increase. However, other values and ranges for the length D6 are within the scope of the present disclosure.

As indicated above, FIGS. 4A-4S are provided as examples. Other examples may differ from what is described with regard FIGS. 4A-4S. For example, fabricating the portion 210a may include additional manufacturing operations, fewer manufacturing operations, or differently arranged manufacturing operations performed by the semiconductor processing tools 102-116 than those described in connection with FIGS. 4A-4S. Additionally, or alternatively, the portion 210a may include additional features, fewer features, different features, differently arranged features, or different materials than those described in connection with FIGS. 4A-4S.

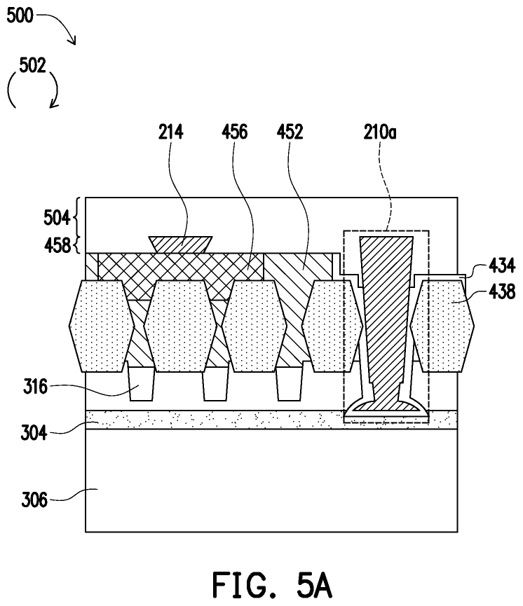

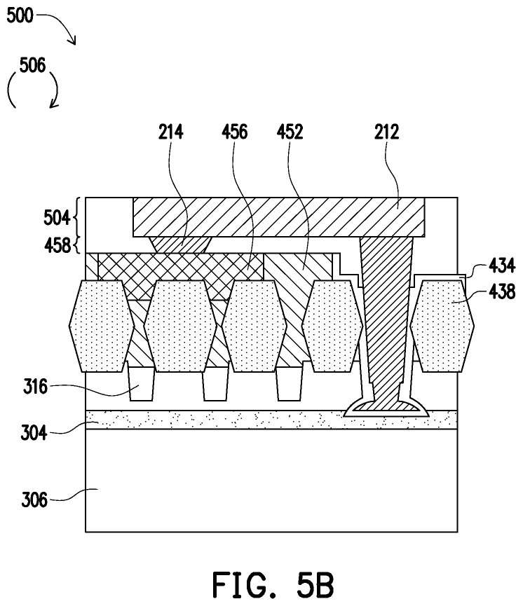

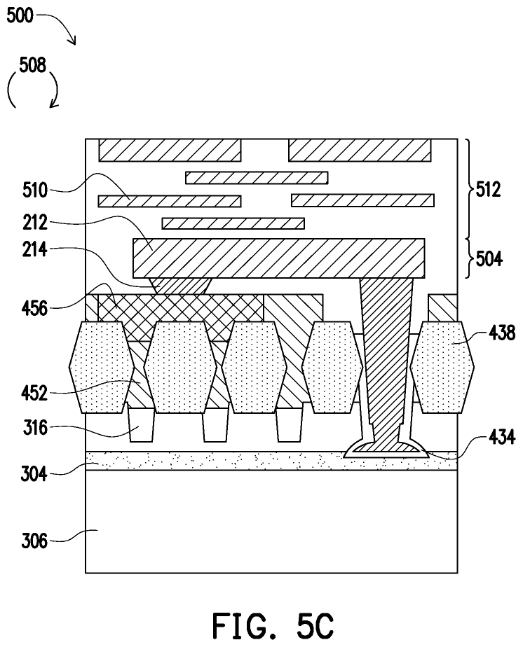

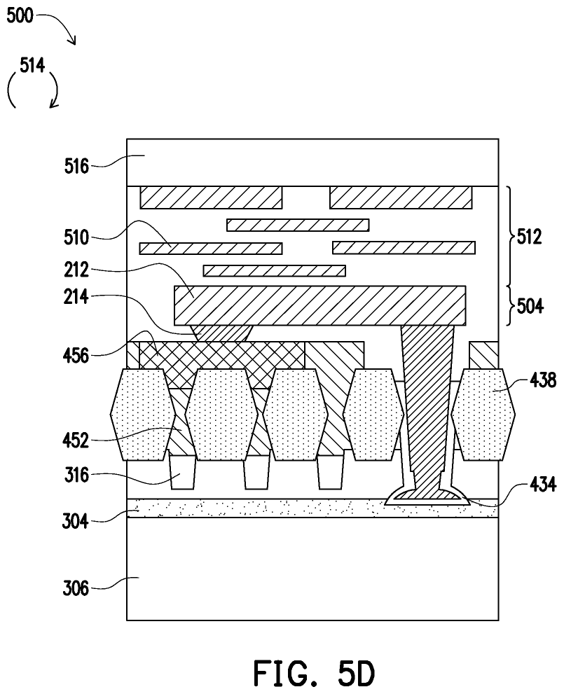

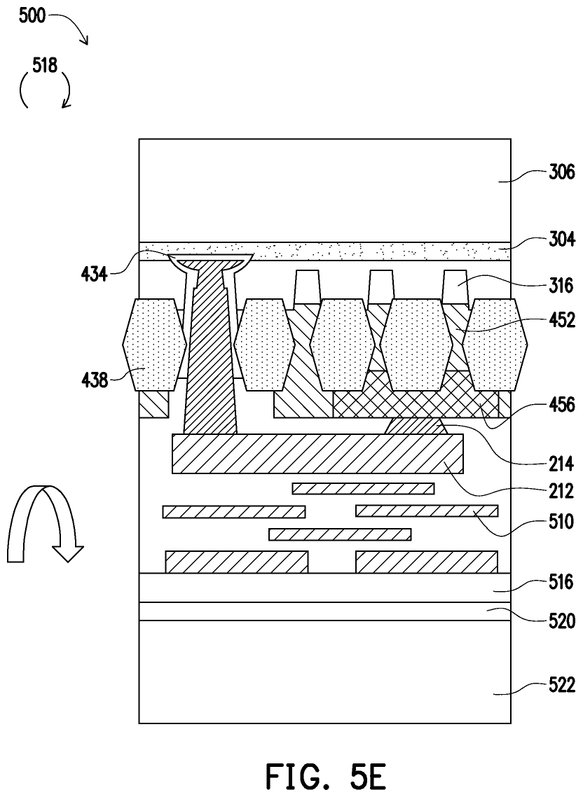

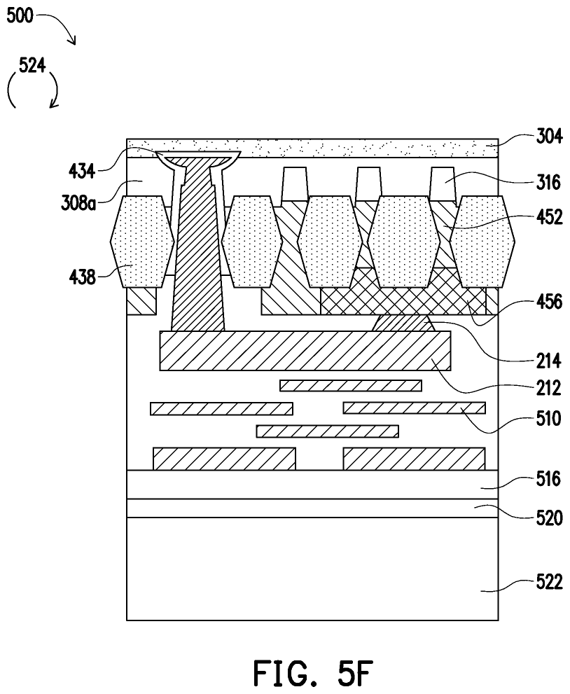

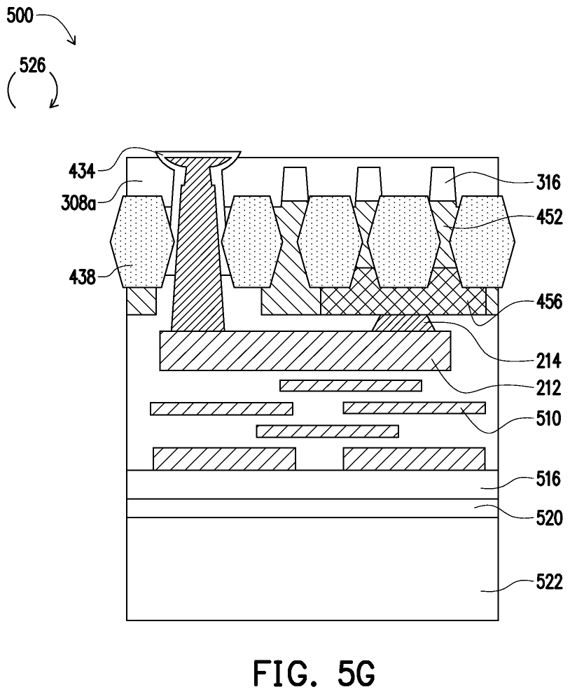

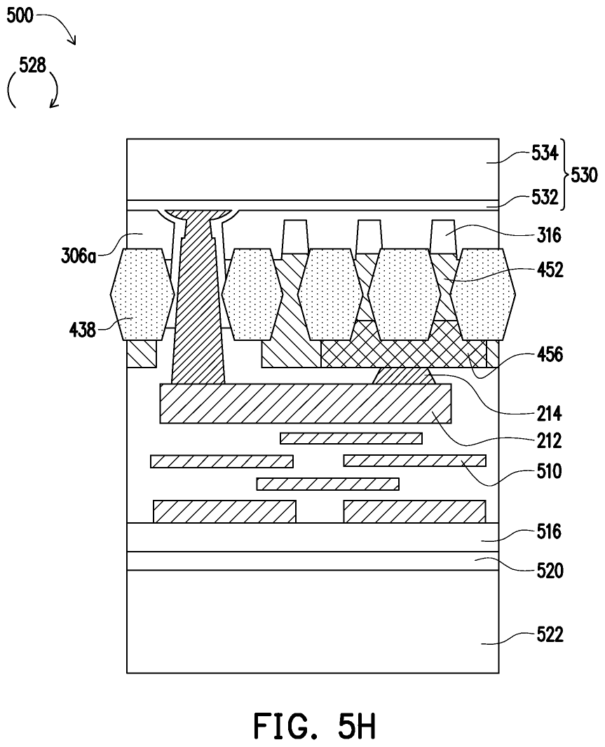

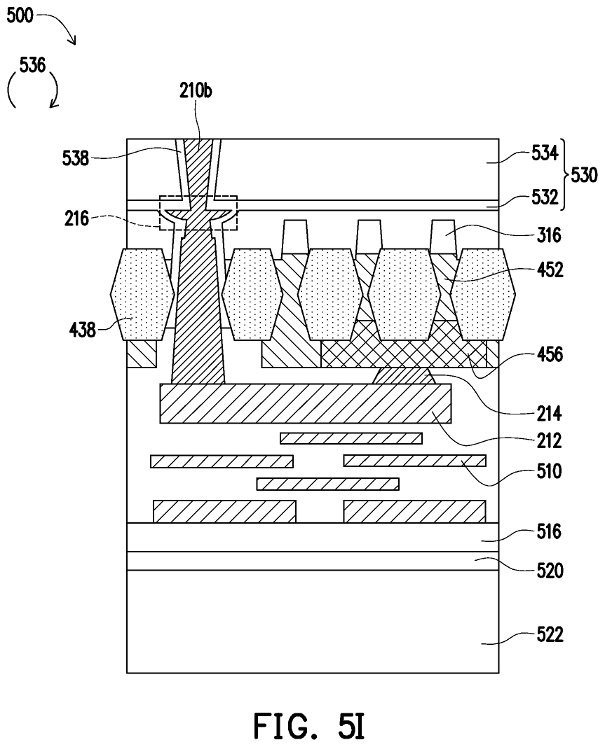

FIGS. 5A-5I are diagrams of an example implementation 500 of forming an example semiconductor device including an interconnect structure and a backside power rail structure described herein. The semiconductor device may correspond to the semiconductor device 200. In FIGS. 5A-5I, various operations are used to form portions of the semiconductor device 200. The portions of the semiconductor device 200 in implementation 500 include the metal layer structure 212 of the semiconductor device 200.

As shown in FIG. 5A, one or more of the semiconductor processing tools 102-116 may perform a series of one or more operations 502 to form a layer of oxide material 504 on the portion 210a, the interconnect structure 214, and the layer of dielectric material 460. As part of the series of one or more operations 502, the deposition tool 102 may deposit the layer of oxide material 504 (e.g., a silicon dioxide (SiO₂) material or another oxide material, among other examples) in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of oxide material 504 after the deposition tool 102 deposits the layer of oxide material 504.

As shown in FIG. 5B, one or more of the semiconductor processing tools 102-116 may perform a series of one or more operations 506 to form the metal layer structure 212. In some implementations, a pattern in a photoresist layer is used to etch the layer of oxide material 504 to form a recess for the metal layer structure 212. In these implementations, the deposition tool 102 forms the photoresist layer on the layer of oxide material 504. The exposure tool 104 exposes the photoresist layer to a radiation source to pattern the photoresist layer. The developer tool 106 develops and removes portions of the photoresist layer to expose the pattern. The etch tool 108 etches the layer of oxide material 504 based on the pattern to form the recess for the metal layer structure 212 in the layer of oxide material 504. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the layer of oxide material 504 based on a pattern.

As shown in FIG. 5C, one or more of the semiconductor processing tools 102-116 may perform a series of one or more operations 508 to form back end of line (BEOL) metal routing structures 510 interleaved with one or more layers of dielectric material 512. In some implementations, the series of one or more operations 508 includes the deposition tool 102 depositing the one or more layers of dielectric material 512 (e.g., a silicon dioxide (SiO₂) material or another dielectric material, among other examples) in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the one or more layers of dielectric material 512 after the deposition tool 102 deposits the one or more layers of dielectric material 512.

Additionally, or alternatively, the series of one or more operations 506 includes the deposition tool 102 and/or the plating tool 112 depositing one or more layers of metal material (e.g., a titanium (Ti) material, a copper (Cu) material, an aluminum (Al) material, or another metal material, among other examples) in a CVD operation, a PVD operation, an ALD operation, an electroplating operation, another deposition operation described above in connection with FIG. 1, and/or another suitable deposition operation. In some implementations, seed layers are first deposited, and the one or more layers of metal material are deposited on the seed layers.

Additionally, or alternatively patterns in one or more photoresist layers are used to etch the one or more layers of metal material to form the BEOL metal routing structures 510. In these implementations, the deposition tool 102 forms the one or more photoresist layers on the one or more layers of metal material. The exposure tool 104 exposes the one or more photoresist layers to a radiation source to pattern the photoresist layer. The developer tool 106 develops and removes portions of the one or more photoresist layers to expose the patterns. The etch tool 108 etches the one or more layers of metal material based on the patterns to form the BEOL metal routing structures 510. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, hard mask layers are used as an alternative technique for etching the one or more layers of metal material based on the patterns.

As shown in FIG. 5D, one or more of the semiconductor processing tools 102-116 may perform a series of one or more operations 514 to form a layer of a high-density plasma oxide material 516 over the BEOL metal routing structures 510 interleaved with the one or more layers of dielectric material 512. As part of the series of one or more operations 514, the deposition tool 102 may deposit the layer of high-density plasma oxide material 516 (e.g., a silicon dioxide (SiO₂) material or another oxide material, among other examples) in a HDP-CVD operation, another type of deposition operation described in connection with FIG. 1, and/or another suitable deposition operation. In some implementations, the planarization tool 110 planarizes the layer of high-density plasma oxide material 516 after the deposition tool 102 deposits the layer of high-density plasma oxide material 516.

As shown in FIG. 5E, one or more of the semiconductor processing tools 102-116 may perform a series of one or more operations 518 that include inverting the structure including the layer of high-density plasma oxide material 516 and bonding the layer of high-density plasma oxide material 516 to another structure including a layer of high-density plasma oxide material 520 on a silicon substrate 522. In some implementations, the structure including the layer of high-density plasma oxide material 520 on the silicon substrate 522 is formed using one techniques similar to those described above. As part of the series of one or more operations 518, the bonding tool 116 may heat the layer of high-density plasma oxide material 516 and the layer of high-density plasma oxide material 520 to form a eutectic system that bonds the layer of high-density plasma oxide material 516 and the layer of high-density plasma oxide material 520.

As shown in FIG. 5F, one or more of the semiconductor processing tools 102-116 may perform a series of one or more operations 524 to remove the silicon substrate 306. For example, the series of one or more operations 524 may include the planarization tool 110 performing a griding operation and/or a CMP operation. Additionally, or alternatively, the etch tool 108 may etch the silicon substrate 306 using a wet chemical etch operation, and/or another type of etch operation. In such cases, the etch tool 108 may use a tetramethyl ammonium hydroxide (TAH) solution or an ammonia (NH₃) solution. Furthermore, and in such cases, the layer of silicon germanium material 304 may perform as an etch stop.

As shown in FIG. 5G, one or more of the semiconductor processing tools 102-116 may perform a series of one or more operations 526 to remove the layer of silicon germanium material 304. For example, the series of one or more operations 526 may include the etch tool 108 etching the layer of silicon germanium material 304 using a wet chemical etch operation, and/or another type of etch operation. In such cases, the etch tool 108 may use a mixed solution including hydrogen peroxide (H₂O₂), acetic acid (CH₃COOH), and/or hydrogen fluoride (HF), Furthermore, and in such cases, the layer of semiconductor material 308a may perform as an etch stop.

As shown in FIG. 5H, a combination of one or more of the semiconductor processing tools 102-116 may perform a series of one or more operations 528 that include forming a plurality of layers 530 over the portion 210a of the interconnect structure 210 and the layer of semiconductor material 308a. The series of one or more operations 528 may include the deposition tool 102 depositing a layer of dielectric material 532 (a silicon nitride (SiN) material or another dielectric material, among other examples) using a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of dielectric material 532 after the deposition tool 102 deposits the layer of dielectric material 532.

Additionally, or alternatively, the series of operations 524 may include the deposition tool 102 depositing a layer of an oxide material 534 (e.g., a silicon dioxide (SiO₂) material or another oxide material, among other examples) using a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of oxide material 534 after the deposition tool 102 deposits the layer of oxide material 534. The layer of oxide material 534 may combine with the layer of dielectric material 532 to form the plurality of layers 530.

As shown in FIG. 5I, a combination of one or more of the semiconductor processing tools 102-116 may perform a series of one or more operations 536 that include forming the portion 210b of the interconnect structure 210. In some implementations, a pattern in a photoresist layer is used to etch the plurality of layers 530 to form a recess for the portion 210b of the interconnect structure 210. In these implementations, the deposition tool 102 forms the photoresist layer on the plurality of layers 530. The exposure tool 104 exposes the photoresist layer to a radiation source to pattern the photoresist layer. The developer tool 106 develops and removes portions of the photoresist layer to expose the pattern. The etch tool 108 etches the plurality of layers based on the pattern to form the recess for the portion 210b in the plurality of layers 530. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the plurality of layers 530 based on a pattern.

Additionally, or alternatively, the series of operations 536 may include deposition tool 102 depositing a layer of dielectric liner material 538 (a silicon nitride (SiN) material or another dielectric material, among other examples) over the plurality of layers 530 and in the recess for the portion 210b using a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of dielectric liner material 538 after the deposition tool 102 deposits the layer of dielectric liner material 538.

Additionally, or alternatively, the series of operations 536 may include the deposition tool 102 depositing a layer of a conductive material (e.g., a titanium nitride (TiN) material or a tungsten (W) material, among other examples) included in the portion 210b using a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of conductive material after the deposition tool 102 deposits the layer of conductive material as part of forming the portion 210b.

As shown in FIG. 5I, the portion 210b passes through the layer of oxide material 534 and the layer of dielectric material 532 to join the portion 210a. Additionally, or alternatively and as shown in FIG. 5I, a dielectric liner (e.g., the layer of dielectric liner material 538) surrounds the portion 210b.

In some implementations, the operations 536 include a laser-plug vertical interconnect access structure formation process to form the portion 210b. In these implementations, a laser tool may be used to form the recess for the portion 210b.

As indicated above, FIGS. 5A-51 are provided as examples. Other examples may differ from what is described with regard Figs. FIGS. 5A-5I. For example, fabricating the portion 210b may include additional manufacturing operations, fewer manufacturing operations, or differently arranged manufacturing operations performed by the semiconductor processing tools 102-116 than those described in connection with FIGS. 5A-5I. Additionally, or alternatively, the portion 210b may include additional features, fewer features, different features, differently arranged features, or different materials than those described in connection with FIGS. 5A-5I.

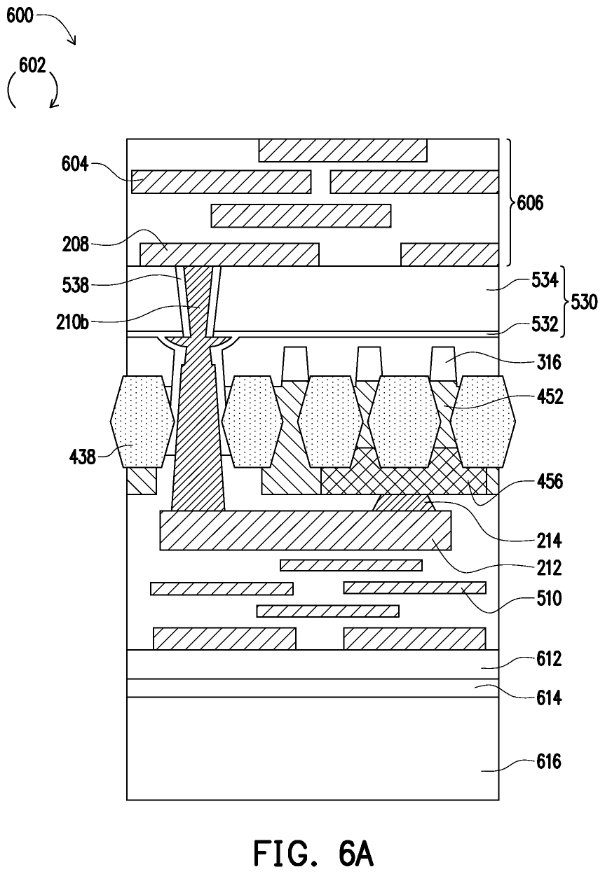

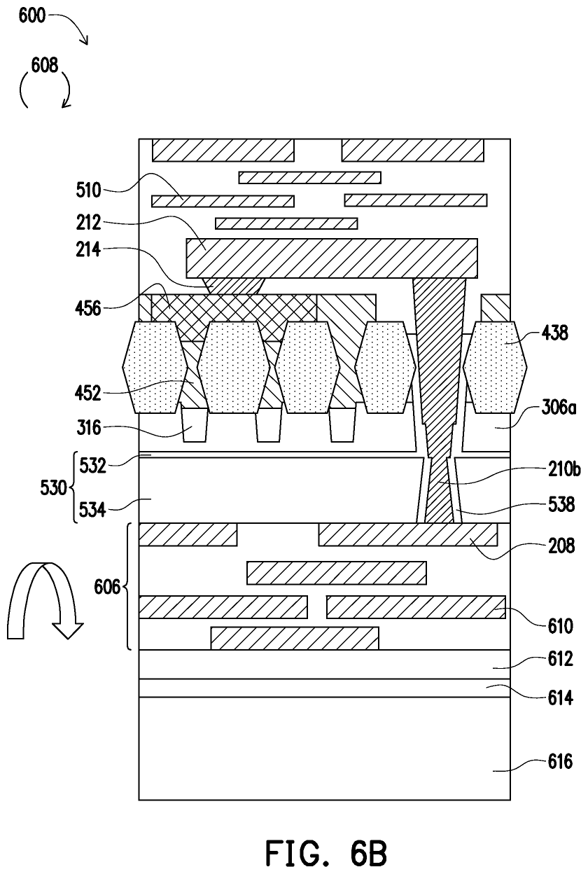

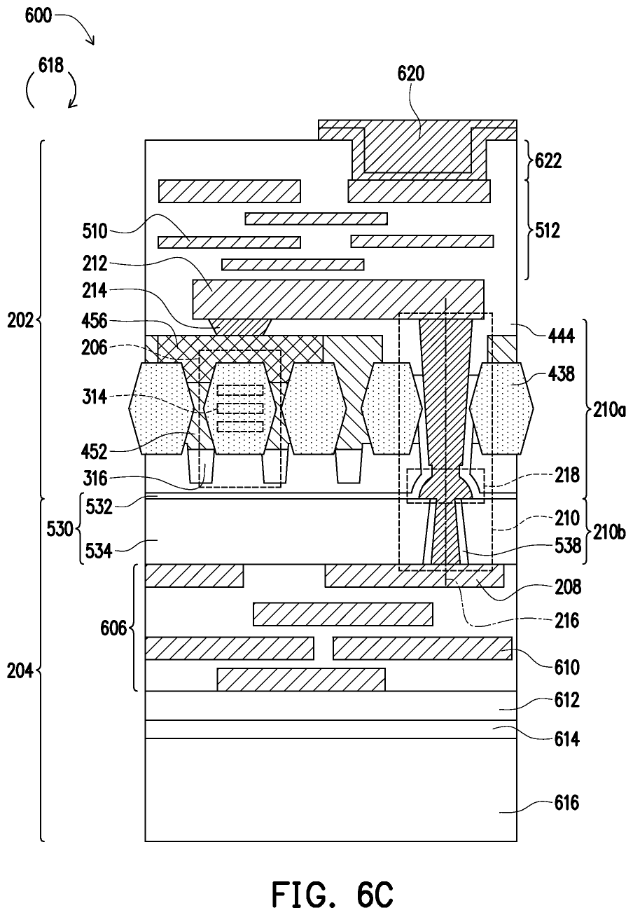

FIGS. 6A-6C are diagrams of an example implementation 600 of forming an example semiconductor device including an interconnect structure and a backside power rail structure described herein. The semiconductor device may correspond to the semiconductor device 200. The portions of the semiconductor device 200 in implementation 600 include the backside power rail structure 208 of the semiconductor device 200.

As shown in FIG. 6A, one or more of the semiconductor processing tools 102-116 may perform a series of one or more operations 602 to form the backside power rail structure 208. In some implementations, the deposition tool 102 and/or the plating tool 112 may deposit a layer of a metal material (e.g., a titanium (Ti) material, a copper (Cu) material, an aluminum (Al) material, or another metal material, among other examples) on the portion of the 210b of the interconnect structure 210 and the plurality of layers 530 in a CVD operation, a PVD operation, an ALD operation, an electroplating operation, another deposition operation described above in connection with FIG. 1, and/or another suitable deposition operation. In some implementations, a seed layer is first deposited, and the layer metal material of metal is deposited on the seed layer.

In some implementations, a pattern in a photoresist layer is used to etch the layer of metal material to form the backside power rail structure 208. In these implementations, the deposition tool 102 forms the photoresist layer on the layer of metal material. The exposure tool 104 exposes the photoresist layer to a radiation source to pattern the photoresist layer. The developer tool 106 develops and removes portions of the photoresist layer to expose the pattern. The etch tool 108 etches layer of metal material based on the pattern to form the backside power rail structure. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the layer of metal material based on a pattern.

In some implementations and as part of the series of operations 602, one or more of the semiconductor processing tools 102-116 may perform operations to form metal routing structures 604 interleaved with one or more layers of dielectric material 606. In these implementations, the series of one or more operations 602 includes the deposition tool 102 depositing the one or more layers of dielectric material 606 (e.g., a silicon dioxide (SiO₂) material or another dielectric material, among other examples) in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the one or more layers of dielectric material 606 after the deposition tool 102 deposits the one or more layers of dielectric material 606.

Additionally, or alternatively, deposition tool 102 and/or the plating tool 112 may deposit one or more layers of metal material (e.g., a titanium (Ti) material, a copper (Cu) material, an aluminum (Al) material, or another metal material, among other examples) in a CVD operation, a PVD operation, an ALD operation, an electroplating operation, another deposition operation described above in connection with FIG. 1, and/or another suitable deposition operation. In some implementations, seed layers are first deposited, and the one or more layers of metal material are deposited on the seed layers.

Additionally, or alternatively patterns in one or more photoresist layers are used to etch the one or more layers of metal material to form the metal routing structures 604. In these implementations, the deposition tool 102 forms the one or more photoresist layers on the one or more layers of metal material. The exposure tool 104 exposes the one or more photoresist layers to a radiation source to pattern the photoresist layer. The developer tool 106 develops and removes portions of the one or more photoresist layers to expose the patterns. The etch tool 108 etches the one or more layers of metal material based on the patterns to form the metal routing structures 604. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, hard mask layers are used as an alternative technique for etching the one or more layers of metal material based on the patterns.

As shown in FIG. 6B, one or more of the semiconductor processing tools 102-116 may perform a series of one or more operations 608 that include inverting the structure including the portion 210b and bonding a surface of the one or more layers of dielectric material 606 and/or a surface of the metal routing structures 610 to a layer of a high-density plasma oxide material 612 over a layer of high-density plasma oxide material 614 over a silicon substrate 616. In some implementations, the layer of high-density plasma oxide material 612 corresponds to the layer of high-density plasma oxide material 516, the layer of high-density plasma oxide material 614 corresponds to the layer of high-density plasma oxide material 520, and the silicon substrate 616 corresponds to the silicon substrate 522 of FIG. 5E (e.g., the referenced layers of FIG. 5E are recovered and/or re-used). In some implementations, the layer of high-density plasma oxide material 612 over the layer of high-density plasma oxide material 614 over the silicon substrate 616 are formed using techniques similar to those described above.

As part of the series of one or more operations 608, the bonding tool 116 may heat the layer of high-density plasma oxide material 612, the one or more layers of dielectric material 606, and/or the metal routing structures 610 to form a eutectic system that bonds the layer of high-density plasma oxide material 612 to the one or more layers of dielectric material 606 and/or the metal routing structures 610.

As shown in FIG. 6C, one or more of the semiconductor processing tools 102-116 may perform a series of one or more operations 618 to form a pad structure 620 in a layer of a dielectric material 622 over the BEOL metal routing structures 510 and on the one or more layers of dielectric material 512. As part of the series of one or more operations 618, deposition tool 102 may deposit the layer of dielectric material 622 (e.g., a silicon dioxide (SiO₂) material or another dielectric material, among other examples) in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the layer of dielectric material 622 after the deposition tool 102 deposits the layer of dielectric material 622.

In some implementations, a pattern in a photoresist layer is used to etch the layer of dielectric material 622 to form a recess for the pad structure 620. In these implementations, the deposition tool 102 forms the photoresist layer on the layer of dielectric material 622. The exposure tool 104 exposes the photoresist layer to a radiation source to pattern the photoresist layer. The developer tool 106 develops and removes portions of the photoresist layer to expose the pattern. The etch tool 108 etches layer of dielectric material 622 based on the pattern to form the recess for the pad structure 620. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the layer of dielectric material 622 to form the recess for the pad structure 620.

As part of the operations 618, the deposition tool 102 and/or the plating tool 112 may deposit the one or more layers of a metal material (e.g., an aluminum (Al) material or another metal material, among other examples) in a CVD operation, a PVD operation, an ALD operation, an electroplating operation, another deposition operation described above in connection with FIG. 1, and/or another suitable deposition operation. In some implementations, a seed layer is first deposited, and the one or more layers of conductive material are deposited over seed layer.

In some implementations, a pattern in a photoresist layer is used to etch the one or more layers of metal material to form the pad structure 620. In these implementations, the deposition tool 102 forms the photoresist layer on the one or more layers of metal material. The exposure tool 104 exposes the photoresist layer to a radiation source to pattern the photoresist layer. The developer tool 106 develops and removes portions of the photoresist layer to expose the pattern. The etch tool 108 etches the one or more layers of metal material based on the pattern to form the pad structure 620. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the one or more layers of metal material based on a pattern.

As shown in FIG. 6C, a device (e.g., the semiconductor device 200) has the portion 202 (e.g., a top portion) including the metal layer structure 212. The device includes the portion 204 (e.g., a bottom portion) below the portion 202. The portion 204 includes the backside power rail structure 208. The device includes the interconnect structure 210 electrically connecting the metal layer structure 212 to the backside power rail structure 208. The interconnect structure 210 includes the portion 210a (e.g., a first portion) located along the central, vertical axis 216 within the portion 202. The portion 210a includes the approximately hemispherical structure 218 at an interface between the portion 202 and the portion 204. The interconnect structure 210 includes the portion 210b (e.g., a second portion) approximately co-located along the central, vertical axis 216 within the portion 204. The portion 210b has an end that joins with the approximately hemispherical structure 218 of the portion 210a.

Additionally, or alternatively, the device includes a transistor structure 206 having a plurality of channel structures 314 (hidden in FIG. 6C by the epitaxial structures 438). The device includes the metal layer structure 212 above the plurality of channel structures 314. The device includes the interconnect structure 214 (e.g., a first interconnect structure) above the transistor structure 206 that electrically connects the transistor structure 206 to the metal layer structure 212. The device includes the interconnect structure 210 (e.g., a second interconnect structure) adjacent to the transistor structure 206. The interconnect structure 210 includes a first end electrically connected to the metal layer structure 212, a second end electrically connected to the backside power rail structure 208, and a bowed-profile portion (e.g., the approximately hemispherical structure 218) between the first end and the second end.

As indicated above, FIGS. 6A-6C are provided as examples. Other examples may differ from what is described with regard FIGS. 6A-6C. For example, fabricating the backside power rail structure 208 may include additional manufacturing operations, fewer manufacturing operations, or differently arranged manufacturing operations performed by the semiconductor processing tools 102-116 than those described in connection with FIGS. 6A-6C. Additionally, or alternatively, the backside power rail structure 208 may include additional features, fewer features, different features, differently arranged features, or different materials than those described in connection with FIGS. 6A-6C.

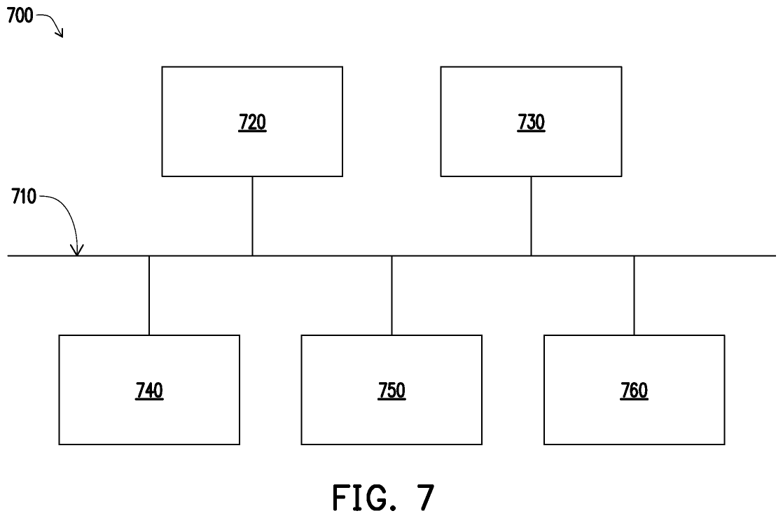

FIG. 7 is a diagram of example components of a device 700 associated with fabricating an interconnect structure that connects to a backside power rail structure described herein. Device 700 may correspond to one or more of the semiconductor processing tools 102-116 of FIG. 1. In some implementations, one or more of the semiconductor processing tools 102-116 include one or more devices 700 and/or one or more components of device 700. As shown in FIG. 7, device 700 may include a bus 710, a processor 720, a memory 730, an input component 740, an output component 750, and a communication component 760.

Bus 710 includes one or more components that enable wired and/or wireless communication among the components of device 700. Bus 710 may couple together two or more components of FIG. 7, such as via operative coupling, communicative coupling, electronic coupling, and/or electric coupling. Processor 720 includes a central processing unit, a graphics processing unit, a microprocessor, a controller, a microcontroller, a digital signal processor, a field-programmable gate array, an application-specific integrated circuit, and/or another type of processing component. Processor 720 is implemented in hardware, firmware, or a combination of hardware and software. In some implementations, processor 720 includes one or more processors capable of being programmed to perform one or more operations or processes described elsewhere herein.

Memory 730 includes volatile and/or nonvolatile memory. For example, memory 730 may include random access memory (RAM), read only memory (ROM), a hard disk drive, and/or another type of memory (e.g., a flash memory, a magnetic memory, and/or an optical memory). Memory 730 may include internal memory (e.g., RAM, ROM, or a hard disk drive) and/or removable memory (e.g., removable via a universal serial bus connection). Memory 730 may be a non-transitory computer-readable medium. Memory 730 stores information, instructions, and/or software (e.g., one or more software applications) related to the operation of device 700. In some implementations, memory 730 includes one or more memories that are coupled to one or more processors (e.g., processor 720), such as via bus 710.

Input component 740 enables device 700 to receive input, such as user input and/or sensed input. For example, input component 740 may include a touch screen, a keyboard, a keypad, a mouse, a button, a microphone, a switch, a sensor, a global positioning system sensor, an accelerometer, a gyroscope, and/or an actuator. Output component 750 enables device 700 to provide output, such as via a display, a speaker, and/or a light-emitting diode. Communication component 760 enables device 700 to communicate with other devices via a wired connection and/or a wireless connection. For example, communication component 760 may include a receiver, a transmitter, a transceiver, a modem, a network interface card, and/or an antenna.

Device 700 may perform one or more operations or processes described herein. For example, a non-transitory computer-readable medium (e.g., memory 730) may store a set of instructions (e.g., one or more instructions or code) for execution by processor 720. Processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry is used instead of or in combination with the instructions to perform one or more operations or processes described herein. Additionally, or alternatively, processor 720 may be configured to perform one or more operations or processes described herein. Thus, implementations described herein are not limited to any specific combination of hardware circuitry and software.

The number and arrangement of components shown in FIG. 7 are provided as an example. Device 700 may include additional components, fewer components, different components, or differently arranged components than those shown in FIG. 7. Additionally, or alternatively, a set of components (e.g., one or more components) of device 700 may perform one or more functions described as being performed by another set of components of device 700.

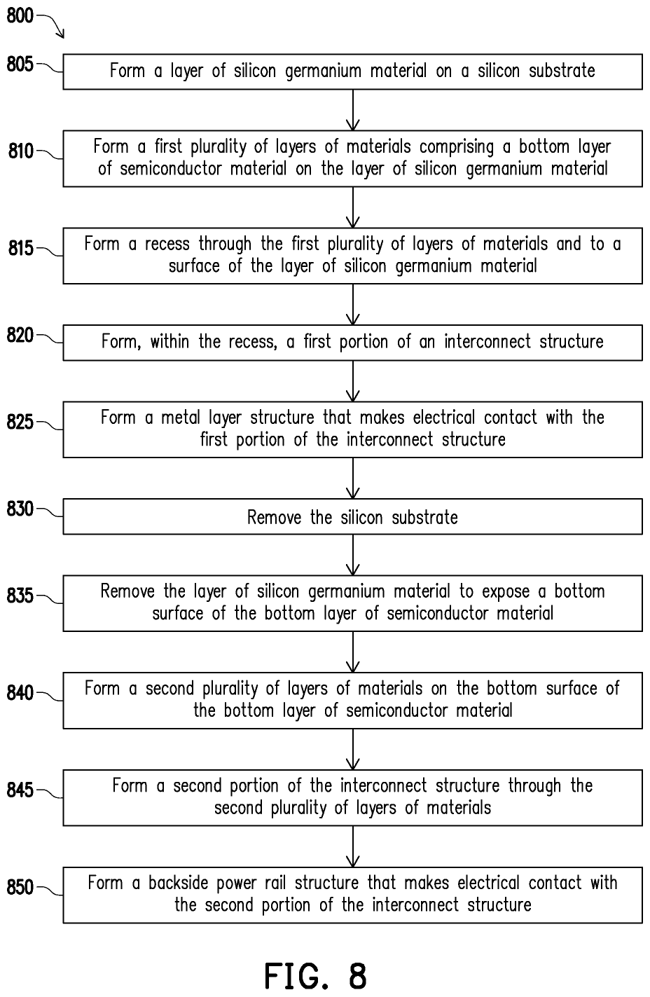

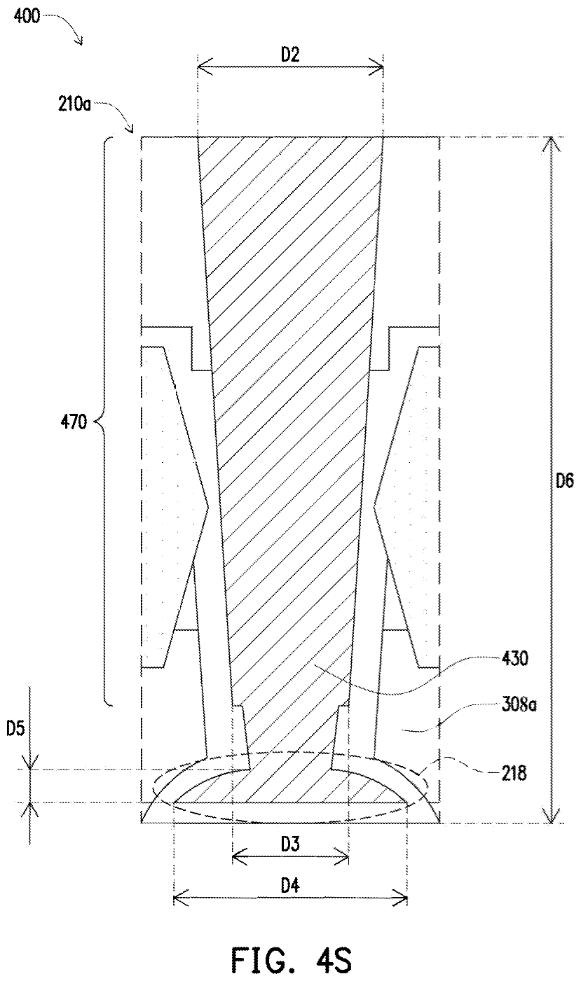

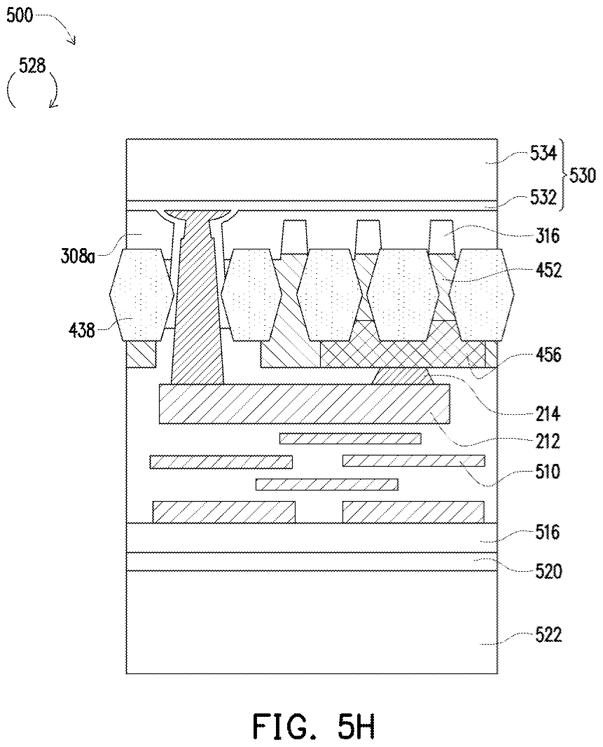

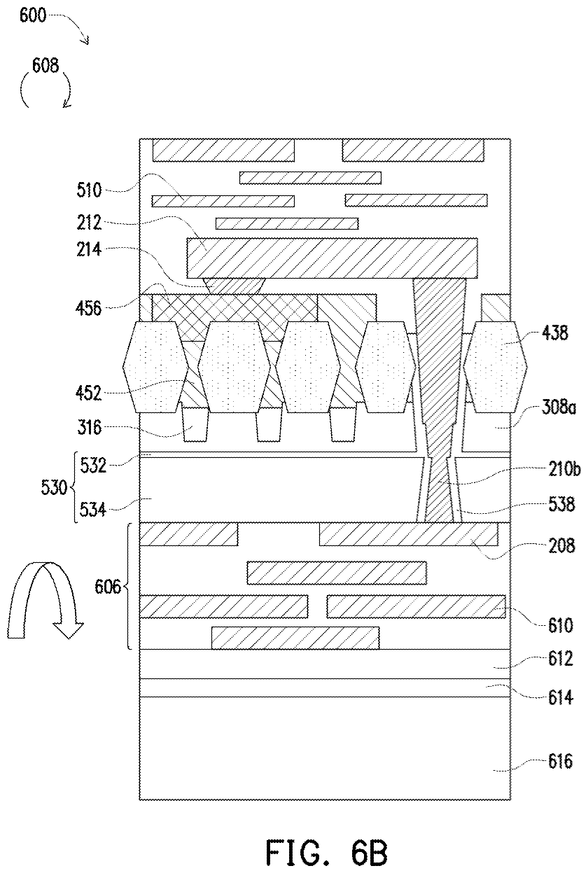

FIG. 8 is a flowchart of an example process associated with forming the example semiconductor device including the interconnect structure and the backside power rail structure described herein. In some implementations, one or more process blocks of FIG. 8 are performed by one or more of the semiconductor processing tools 102-116. Additionally, or alternatively, one or more process blocks of FIG. 8 may be performed by one or more components of device 700, such as processor 720, memory 730, input component 740, output component 750, and/or communication component 760.

As shown in FIG. 8, process 800 may include forming a layer of silicon germanium material on a silicon substrate (block 805). For example, a combination of one or more of the semiconductor processing tools 112-116 may perform a series of one or more operations 302 to form a layer of silicon germanium material 304 on a silicon substrate 306, as described above.

As further shown in FIG. 8, process 800 may include forming a first plurality of layers of materials including a bottom layer of semiconductor material on the layer of silicon germanium material (block 810). For example, a combination of one or more of the semiconductor processing tools 112-116 may perform a series of one or more operations 302 to form a first plurality of layers (e.g., the plurality of layers of material 308) including a bottom layer of semiconductor material (e.g., the layer of semiconductor material 308a) on the layer of silicon germanium material 304, as described above. In some implementations, the first plurality of layers of materials are arranged in a first direction that is perpendicular to the silicon substrate 306.

As further shown in FIG. 8, process 800 may include forming a recess through the first plurality of layers of materials and to a surface of the layer of silicon germanium material (block 815). For example, a combination of one or more of the semiconductor processing tools 112-116 may perform a series of one or more operations 320 to form a recess 322 through the first plurality of layers of materials and to a surface of the layer of silicon germanium material 304, as described above.

As further shown in FIG. 8, process 800 may include forming, within the recess, a first portion of an interconnect structure (block 820). For example, a combination of one or more of the semiconductor processing tools 112-116 may perform a series of one or more operations 468 to form, within the recess 322, a first portion (e.g., the portion 210a) of an interconnect structure 210, as described above.

As further shown in FIG. 8, process 800 may include forming a metal layer structure that makes electrical contact with the first portion of the interconnect structure (block 825). For example, a combination of one or more of the semiconductor processing tools 112-116 may perform a series of one or more operations 506 to form a metal layer structure 212 that makes electrical contact with the first portion of the interconnect structure 210, as described above.

As further shown in FIG. 8, process 800 may include removing the silicon substrate (block 830). For example, a combination of one or more of the semiconductor processing tools 112-116 may perform a series of one or more operations 524 to remove the silicon substrate 306, as described above.

As further shown in FIG. 8, process 800 may include removing the layer of silicon germanium material to expose a bottom surface of the bottom layer of semiconductor material (block 835). For example, a combination of one or more of the semiconductor processing tools 112-116 may perform a series of one or more operations 524 to remove the layer of silicon germanium material to expose a bottom surface of the bottom layer of semiconductor material, as described above.

As further shown in FIG. 8, process 800 may include forming a second plurality of layers of materials on the bottom surface of the bottom layer (block 840). For example, a combination of one or more of the semiconductor processing tools 112-116 may perform a series of one or more operations 528 to form a second plurality of layers of materials (e.g., the plurality of layers 530) on the bottom surface of the bottom layer, as described above. In some implementations, the second plurality of layers of materials are arranged in a second direction that is perpendicular to the bottom layer of semiconductor material and opposite the first direction.

As further shown in FIG. 8, process 800 may include forming a second portion of the interconnect structure through the second plurality of layers of materials (block 845). For example, a combination of one or more of the semiconductor processing tools 112-116 may perform a series of one or more operations 536 to form a second portion (e.g., the portion 210b) of the interconnect structure 210 through the second plurality of layers of materials, as described above.

As further shown in FIG. 8, process 800 may include forming a backside power rail structure that makes electrical contact with the second portion of the interconnect structure (block 850). For example, a combination of one or more of the semiconductor processing tools 112-116 may perform a series of one or more operations 602 to form a backside power rail structure 208 that makes electrical contact with the second portion of the interconnect structure 210, as described above.

Process 800 may include additional implementations, such as any single implementation or any combination of implementations described below and/or in connection with one or more other processes described elsewhere herein.

In a first implementation, forming the layer of silicon germanium material includes forming the layer of silicon germanium material 304 to a thickness D1 that is included in a range of approximately 10 nanometers to approximately 100 nanometers.

In a second implementation, alone or in combination with the first implementation, forming the layer of silicon germanium material includes forming a layer of silicon germanium material doped with boron.

In a third implementation, alone or in combination with one or more of the first and second implementations, forming the recess 322 includes performing a dry-etching operation to form an elongated region 324 of the recess 322 and performing a wet chemical etch operation to form an approximately hemispherical region 326 at a bottom of the recess 322 below the elongated region 324.

In a fourth implementation, alone or in combination with one or more of the first through third implementations, performing the wet chemical etch operation comprises using a tetramethyl ammonium hydroxide solution to laterally etch the approximately hemispherical region 326 at the bottom of the recess 322 below the elongated region 324.

In a fifth implementation, alone or in combination with one or more of the first through fourth implementations, performing the wet chemical etch operation includes using an ammonia solution to laterally etch the approximately hemispherical region 326 at the bottom of the recess 322 below the elongated region 324.

In a sixth implementation, alone or in combination with one or more of the first through fifth implementations, forming the first portion of the interconnect structure 210 includes forming a liner (e.g., the layer of dielectric liner material 404) over interior surfaces of the recess 322 including the approximately hemispherical region 326, forming a plug structure 408 over the liner and between the interior surfaces of the recess 322, and removing portions of the plug structure to leave a segment of the first portion (e.g., the remaining portion of the plug structure 408 after the series of one or more operations 410) of the interconnect structure 210 at the bottom of the recess 322. In some implementations, the segment extends into the approximately hemispherical region 326.

In a seventh implementation, alone or in combination with one or more of the first through sixth implementations, forming the second portion of the interconnect structure 210 through the second plurality of layers of materials includes joining the second portion of the interconnect structure 210 to the first portion of the interconnect structure 210.

In an eighth implementation, alone or in combination with one or more of the first through seventh implementations, forming the second portion of the interconnect structure through the second plurality of layers of materials includes using a laser-plug vertical interconnect access structure formation process.

In a ninth implementation, alone or in combination with one or more of the first through eighth implementations, removing the silicon substrate 306 includes performing a grinding operation, performing a chemical mechanical planarization operation, and performing a chemical wet etch operation (e.g., the series of one or more operations 526) using a tetramethyl ammonium hydroxide solution or an ammonia solution In some implementations, the layer of silicon germanium material 304 performs as an etch stop.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

Some implementations described herein provide a semiconductor device and methods of formation. The semiconductor device includes a transistor structure that is electrically connected to a metal layer. Described techniques include forming an interconnect structure that electrically connects the metal layer to a backside power rail structure. The techniques include forming a first portion of the interconnect structure using a layer of silicon germanium as an etch stop and, after removal of the layer of the silicon germanium, forming a second portion of the interconnect structure.

In this way, manufacturing efficiencies relative to manufacturing efficiencies associated with not using the layer of silicon germanium may be increased. Additionally, a likelihood of the interconnect structure making electrical contact with the backside rail structure may increase due to improve a performance of the semiconductor device relative to a semiconductor device fabricated not using the layer of silicon germanium.

As described in greater detail above, some implementations described herein provide a device. The device includes a top portion includes a metal layer structure. The device includes a bottom portion below the top portion including a backside power rail structure. The device includes an interconnect structure electrically connecting the metal layer structure to the backside power rail structure. The interconnect structure includes a first portion located along a central, vertical axis within the top portion. The first portion has an approximately hemispherical structure at an interface between the top portion and the bottom portion. The interconnect structure includes a second portion approximately co-located along the central, vertical axis within the bottom portion. The second portion has an end that joins with the approximately hemispherical structure of the first portion.

As described in greater detail above, some implementations described herein provide a device. The device includes a transistor structure having a plurality of channel structures. The device includes a metal layer structure above the plurality of channel structures. The device includes a first interconnect structure above the transistor structure that electrically connects the transistor structure to the metal layer structure. The device includes a second interconnect structure adjacent to the transistor structure. The second interconnect structure includes a first end electrically connected to the metal layer structure, a second end electrically connected to a backside power rail structure, and a bowed-profile portion between the first end and the second end.

As described in greater detail above, some implementations described herein provide a method. The method includes forming a layer of silicon germanium material on a silicon substrate. The method includes forming a first plurality of layers of materials including a bottom layer of semiconductor material on the layer of silicon germanium material, where the first plurality of layers are arranged in a first direction that is perpendicular to the silicon substrate. The method includes forming a recess through the first plurality of layers of materials and to a surface of the layer of silicon germanium material. The method includes forming, within the recess, a first portion of an interconnect structure. The method includes forming a metal layer structure that makes electrical contact with the first portion of the interconnect structure. The method includes removing the silicon substrate. The method includes removing the layer of silicon germanium material to expose a bottom surface of the bottom layer of semiconductor material. The method includes forming a second plurality of layers of materials on the bottom surface of the bottom layer of semiconductor material, where the second plurality of layers of materials are arranged in a second direction that is perpendicular to the bottom layer of semiconductor material and opposite the first direction. The method includes forming a second portion of the interconnect structure through the second plurality of layers of materials. The method includes forming a backside power rail structure that makes electrical contact with the second portion of the interconnect structure.

As used herein, the terms “substantially” and “approximately” mean “within reasonable tolerances of manufacturing and measurement.” As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a top portion comprising a metal layer structure;
a bottom portion below the top portion comprising a backside power rail structure; and
an interconnect structure electrically connecting the metal layer structure to the backside power rail structure and comprising:
a first portion located along a central, vertical axis within the top portion and comprising an approximately hemispherical structure at an interface between the top portion and the bottom portion; and
a second portion approximately co-located along the central, vertical axis within the bottom portion and comprising an end that joins with the approximately hemispherical structure of the first portion.

2. The device of claim 1, wherein the first portion of the interconnect structure further comprises:
an elongated structure electrically connected to the approximately hemispherical structure, wherein the elongated structure comprises:
a top width that is included in a range of approximately 15 nanometers to approximately 100 nanometers, and
a bottom width that is included in a range of approximately 10 nanometers to approximately 50 nanometers.

3. The device of claim 1, wherein the approximately hemispherical structure comprises:
a bottom surface having a width that is included in a range of approximately 20 nanometers to approximately 60 nanometers.

4. The device of claim 1, wherein the approximately hemispherical structure comprises:
a height that is include in a range of approximately 5 nanometers to approximately 20 nanometers.

5. The device of claim 1, wherein a length of the first portion of the interconnect structure is included in a range of approximately 100 nanometers to approximately 1000 nanometers.

6. A device, comprising:
a transistor structure comprising a plurality of channel structures;
a metal layer structure above the plurality of channel structures;
a first interconnect structure above the transistor structure and electrically connecting the transistor structure to the metal layer structure; and
a second interconnect structure adjacent to the transistor structure comprising:
a first end electrically connected to the metal layer structure;
a second end electrically connected to a backside power rail structure; and
a bowed-profile portion between the first end and the second end.

7. The device of claim 6, wherein the transistor structure corresponds to a fin field-effect transistor structure or a gate-all-around transistor structure.

8. The device of claim 6, wherein the second interconnect structure comprises:
a tapered portion between the first end and the bowed-profile portion.

9. The device of claim 6, wherein the second interconnect structure passes through a layer of a silicon material, a layer of a silicon nitride material, and a layer of an oxide material.

10. The device of claim 6, further comprising:
a dielectric liner surrounding a portion of the second interconnect structure.

11. A method, comprising:
forming a layer of silicon germanium material on a silicon substrate;
forming a first plurality of layers of materials comprising a bottom layer of semiconductor material on the layer of silicon germanium material,
wherein the first plurality of layers of materials are arranged in a first direction that is perpendicular to the silicon substrate;
forming a recess through the first plurality of layers of materials and to a surface of the layer of silicon germanium material,
forming, within the recess, a first portion of an interconnect structure;
forming a metal layer structure that makes electrical contact with the first portion of the interconnect structure;
removing the silicon substrate;
removing the layer of silicon germanium material to expose a bottom surface of the bottom layer of semiconductor material;
forming a second plurality of layers of materials on the bottom surface of the bottom layer of semiconductor material,
wherein the second plurality of layers of materials are arranged in a second direction that is perpendicular to the bottom layer of semiconductor material and opposite the first direction;
forming a second portion of the interconnect structure through the second plurality of layers of materials; and
forming a backside power rail structure that makes electrical contact with the second portion of the interconnect structure.

12. The method of claim 11, wherein forming the layer of silicon germanium material comprises:
forming the layer of silicon germanium material to a thickness that is included in a range of approximately 10 nanometers to approximately 100 nanometers.

13. The method of claim 11, wherein forming the layer of silicon germanium material comprises:
forming a layer of silicon germanium material doped with boron.

14. The method of claim 11, wherein forming the recess comprises:
performing a dry-etching operation to form an elongated region of the recess; and
performing a wet chemical etch operation to form an approximately hemispherical region at a bottom of the recess below the elongated region.

15. The method of claim 14, wherein performing the wet chemical etch operation comprises:
using a tetramethyl ammonium hydroxide solution to laterally etch the approximately hemispherical region at the bottom of the recess below the elongated region.

16. The method of claim 14, wherein performing the wet chemical etch operation comprises:
using an ammonia solution to laterally etch the approximately hemispherical region at the bottom of the recess below the elongated region.

17. The method of claim 14, wherein forming the first portion of the interconnect structure comprises:
forming a liner over interior surfaces of the recess including the approximately hemispherical region;
forming a plug structure over the liner and between the interior surfaces of the recess; and
removing portions of the plug structure to leave a segment of the first portion of the interconnect structure at the bottom of the recess,
wherein the segment extends into the approximately hemispherical region.

18. The method of claim 11, wherein forming the second portion of the interconnect structure through the second plurality of layers of materials comprises:
joining the second portion of the interconnect structure to the first portion of the interconnect structure.

19. The method of claim 11, wherein forming the second portion of the interconnect structure through the second plurality of layers of materials comprises:
using a laser-plug vertical interconnect access structure formation process.

20. The method of claim 11, wherein removing the silicon substrate comprises:
performing a grinding operation;
performing a chemical mechanical planarization operation; and
performing a wet chemical etch operation using a tetramethyl ammonium hydroxide solution or an ammonia solution,
wherein the layer of silicon germanium material performs as an etch stop.
